(19) United States
(12) Patent Application Publication
(10) Pub. No.: US 2026/0254936 A1
(43) Pub. Date: Aug. 27, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Jeong Woo PARK, Yongin-si (KR); Beom Shik KIM, Yongin-si (KR); Su Yeon SIM, Yongin-si (KR); Su Bin JUNG, Yongin-si (KR)

(21) Appl. No.: 19/428,415

(22) Filed: Dec. 22, 2025

(30) Foreign Application Priority Data
Feb. 26, 2025 (KR) 10-2025-0025222

(51) Int. Cl. H04N 13/359; G02B 30/25; G02B 30/28; G02F 1/13; G02F 1/1362; G02F 1/1368; H04N 13/305

(52) U.S. Cl. CPC H04N 13/359; G02B 30/25; G02B 30/28; G02F 1/1323; G02F 1/136209; G02F 1/13624; G02F 1/1368; H04N 13/305

(57) ABSTRACT

A display device includes a display panel including a plurality of emission areas and a black matrix disposed between the plurality of emission areas, a plurality of second driving electrodes disposed on the display panel and overlapping the plurality of emission areas, respectively, a plurality of first driving electrodes disposed on the plurality of second driving electrodes and overlapping the plurality of emission areas, respectively, a driving liquid crystal disposed between the plurality of second driving electrodes and the plurality of first driving electrodes, and an optical lens unit disposed on the plurality of first driving electrodes and including a plurality of lenses.

### CROSS-REFERENCE TO RELATED APPLICATIONS

This application claims priority under 35 U.S.C. § 119 to Korean Patent Application No. 10-2025-0025222, filed on Feb. 26, 2025, the disclosure of which is incorporated by reference herein in its entirety.

### TECHNICAL FIELD

Embodiments of the present disclosure relate to a display device and an electronic device including the same.

### DISCUSSION OF RELATED ART

Advances in communication technology and media have expanded the use of display devices for presenting images in a wide variety of locations and environments. Examples of such display devices include liquid crystal displays (LCDs) and organic light emitting diode (OLED) displays, which have become widely adopted.

More recently, stereoscopic image display devices have been developed that divide and project images from a display device into space in front of the display using a lens array. Such devices include binocular parallax-type stereoscopic displays, which separate and present left-eye and right-eye images to produce a three-dimensional effect based on binocular parallax, and light field-type stereoscopic displays, which converge light emitted from each lens in the lens array toward specific view areas where the display is observed. Ongoing research in light field-type stereoscopic displays seeks to enhance the three-dimensional (3D) effect by increasing the number of distinct view areas.

### SUMMARY

Embodiments of the present disclosure provide a display device capable of simultaneously implementing a two-dimensional image and a three-dimensional image.

According to various embodiments of the present disclosure, a display device includes a display panel including a plurality of emission areas and a black matrix disposed between the plurality of emission areas, a plurality of second driving electrodes disposed on the display panel and overlapping the plurality of emission areas, respectively, a plurality of first driving electrodes disposed on the plurality of second driving electrodes and overlapping the plurality of emission areas, respectively, a driving liquid crystal disposed between the plurality of second driving electrodes and the plurality of first driving electrodes, and an optical lens unit disposed on the plurality of first driving electrodes and including a plurality of lenses.

According to various embodiments of the present disclosure, the plurality of emission areas may include a first emission area configured to emit light having a first color, a second emission area configured to emit light having a second color, and a third emission area configured to emit light having a third color.

According to various embodiments of the present disclosure, the first color, the second color, and the third color comprise red, green, and blue, respectively.

According to various embodiments of the present disclosure, the plurality of emission areas may include a first pixel emission area and a second pixel emission area, and each of the first pixel emission area and the second pixel emission area may include a first emission area configured to emit light having a first color, a second emission area configured to emit light having a second color, and a third emission area configured to emit light having a third color.

According to various embodiments of the present disclosure, the first color, the second color, and the third color comprise, red, green, and blue, respectively.

According to various embodiments of the present disclosure, the plurality of emission areas may include an emission area disposed in a first area and an emission area disposed in a second area, and the plurality of first driving electrodes may include a first driving electrode disposed in the first area and a first driving electrode disposed in the second area.

According to various embodiments of the present disclosure, a first voltage applied to the first driving electrode disposed in the first area may be different from a second voltage applied to the first driving electrode disposed in the second area.

According to various embodiments of the present disclosure, the first voltage may be lower than the second voltage.

According to various embodiments of the present disclosure, the plurality of emission areas may include an emission area disposed in a first area and an emission area disposed in a second area, and the plurality of second driving electrodes may include a second driving electrode disposed in the first area and a second driving electrode disposed in the second area.

According to various embodiments of the present disclosure, a third voltage applied to the second driving electrode disposed in the first area may be different from a fourth voltage applied to the second driving electrode disposed in the second area.

According to various embodiments of the present disclosure, the third voltage may be lower than the fourth voltage.

According to various embodiments of the present disclosure, the plurality of first driving electrodes may include a first driving electrode disposed in the first area and a first driving electrode disposed in the second area.

According to various embodiments of the present disclosure, a first voltage applied to the first driving electrode disposed in the first area may be different from a second voltage applied to the first driving electrode disposed in the second area.

According to various embodiments of the present disclosure, a difference between a first voltage applied to the first driving electrode disposed in the first area and a third voltage applied to the second driving electrode disposed in the first area may be different from a difference between a second voltage applied to the first driving electrode disposed in the second area and a fourth voltage applied to the second driving electrode disposed in the second area.

According to various embodiments of the present disclosure, the difference between the first voltage applied to the first driving electrode disposed in the first area and the third voltage applied to the second driving electrode disposed in the first area may be smaller than the difference between the second voltage applied to the first driving electrode disposed in the second area and the fourth voltage applied to the second driving electrode disposed in the second area.

According to various embodiments of the present disclosure, an electronic device includes a processor configured to provide an image signal, a display device configured to receive an image signal provided from the processor and display an image, and a power device configured to supply power to the display device. The display device includes a display panel including a plurality of emission areas and a black matrix disposed between the plurality of emission areas, a plurality of second driving electrodes disposed on the display panel and overlapping the plurality of emission areas, respectively, a plurality of first driving electrodes disposed on the plurality of second driving electrodes and overlapping the plurality of emission areas, respectively, a driving liquid crystal disposed between the plurality of second driving electrodes and the plurality of first driving electrodes, and an optical lens unit disposed on the plurality of first driving electrodes and including a plurality of lenses.

According to various embodiments of the present disclosure, the plurality of emission areas may include a first emission area configured to emit light having a first color, a second emission area configured to emit light having a second color, and a third emission area configured to emit light having a third color.

According to various embodiments of the present disclosure, the plurality of emission areas may include an emission area disposed in a first area and an emission area disposed in a second area, and the plurality of first driving electrodes may include a first driving electrode disposed in the first area and a first driving electrode disposed in the second area.

According to various embodiments of the present disclosure, the plurality of second driving electrodes may include a second driving electrode disposed in the first area and a second driving electrode disposed in the second area.

According to various embodiments of the present disclosure, a difference between a first voltage applied to the first driving electrode disposed in the first area and a third voltage applied to the second driving electrode disposed in the first area may be different from a difference between a second voltage applied to the first driving electrode disposed in the second area and a fourth voltage applied to the second driving electrode disposed in the second area.

With a display device according to an embodiment of the present disclosure, by forming a plurality of driving electrodes corresponding to a size of a sub-pixel level, it is possible to simultaneously implement a two-dimensional image and a three-dimensional image in one display device.

With a display device according to an embodiment of the present disclosure, by forming a plurality of driving electrodes corresponding to a size of a pixel level, it is possible to simultaneously implement a two-dimensional image and a three-dimensional image in one display device.

With a display device according to an embodiment of the present disclosure, by forming a plurality of driving electrodes corresponding to a size of a unit pixel level, it is possible to simultaneously implement a two-dimensional image and a three-dimensional image in one display device.

### BRIEF DESCRIPTION OF THE DRAWINGS

The above and other aspects and features of the present disclosure will become more apparent by describing in detail embodiments thereof with reference to the accompanying drawings, in which:

FIG. 1 is an exploded perspective view illustrating a display device according to an embodiment of the present disclosure;

FIG. 2 is a perspective view of the display device illustrated in FIG. 1;

FIG. 3 is a cross-sectional view illustrating a portion of the display device including emission areas;

FIG. 4 is a cross-sectional view illustrating a first type of light field display in which a two-dimensional image is implemented;

FIG. 5 is a cross-sectional view illustrating the first type of light field display in which a three-dimensional image is implemented;

FIG. 6 is a cross-sectional view illustrating a second type of light field display in which a two-dimensional image is implemented;

FIG. 7 is a cross-sectional view illustrating the second type of light field display in which a three-dimensional image is implemented;

FIG. 8 is a plan view illustrating an arrangement structure of pixels according to various embodiments of the present disclosure;

FIG. 9 is a plan view illustrating an arrangement structure of pixels according to various embodiments of the present disclosure;

FIG. 10 is a plan view illustrating an arrangement structure of pixels according to various embodiments of the present disclosure;

FIG. 11 is a plan view illustrating an arrangement structure of pixels according to various embodiments of the present disclosure;

FIG. 12 is a cross-sectional view illustrating a display device according to an embodiment of the present disclosure;

FIG. 13 is a cross-sectional view illustrating a display device according to an embodiment of the present disclosure;

FIG. 14 is a cross-sectional view illustrating a display device according to an embodiment of the present disclosure;

FIG. 15 is a cross-sectional view illustrating a modified example of FIG. 14;

FIG. 16 is a plan view illustrating a driving electrode disposed in a first area of a display device according to an embodiment of the present disclosure;

FIG. 17 is a plan view illustrating a driving electrode disposed in a second area of the display device according to an embodiment of the present disclosure;

FIG. 18 is a plan view illustrating a display device according to an embodiment of the present disclosure;

FIG. 19 is a plan view illustrating the display device according to an embodiment of the present disclosure;

FIGS. 20 and 21 are plan views illustrating transistors disposed in a display device according to an embodiment of the present disclosure;

FIG. 22 is a block diagram of an electronic device according to an embodiment of the present disclosure; and

FIG. 23 is schematic views of electronic devices according to various embodiments of the present disclosure.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

Embodiments of the present disclosure relate to a display device configured to selectively implement two-dimensional (2D) and three-dimensional (3D) image modes, including simultaneous implementation of both modes in different regions of a single display panel. The display device may include an optical member having a refractive index anisotropy and a polarization control unit configured to control whether light emitted from the display panel is refracted by the optical member. By controlling the refraction state for different areas of the display, embodiments may enable some regions to output 2D images while other regions output 3D images at the same time.

In an embodiment, the display panel includes a plurality of emission areas corresponding to sub-pixels of different colors, and a plurality of driving electrodes is formed to overlap the emission areas. The driving electrodes are arranged and driven so that light emitted from selected emission areas has a controlled linear polarization direction before entering the optical member. Depending on the polarization state, the light may travel straight through the optical member without refraction, or it may be refracted to direct the light toward different viewing angles for 3D image formation.

In an embodiment, the plurality of driving electrodes is implemented at different granularities, such as a sub-pixel level, pixel level, or unit pixel level, to facilitate control over localized image dimensionality. By applying different voltage schemes to the electrodes in respective regions of the display, the arrangement of liquid crystal material in the polarization control unit is varied to produce different polarization states in corresponding areas. This may enable precise mapping of 2D and 3D image zones across the display surface while maintaining image quality in both modes.

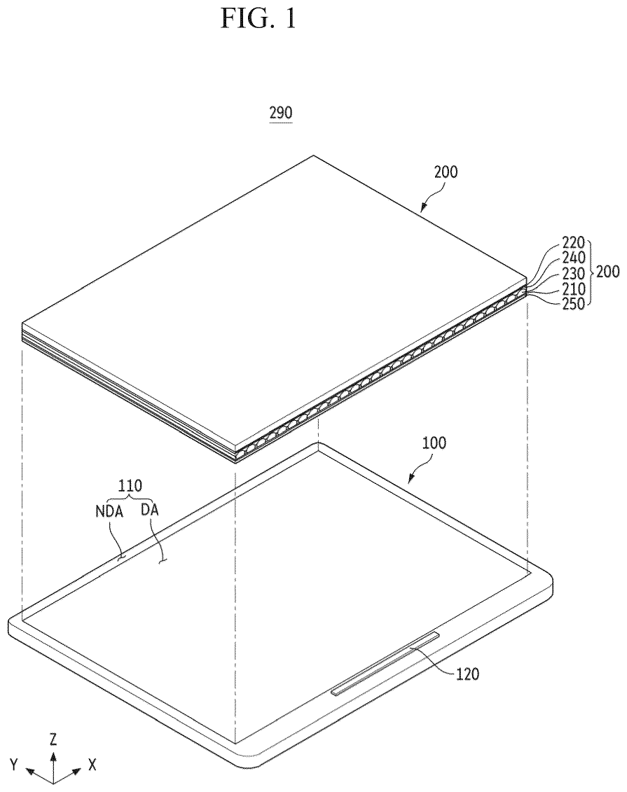

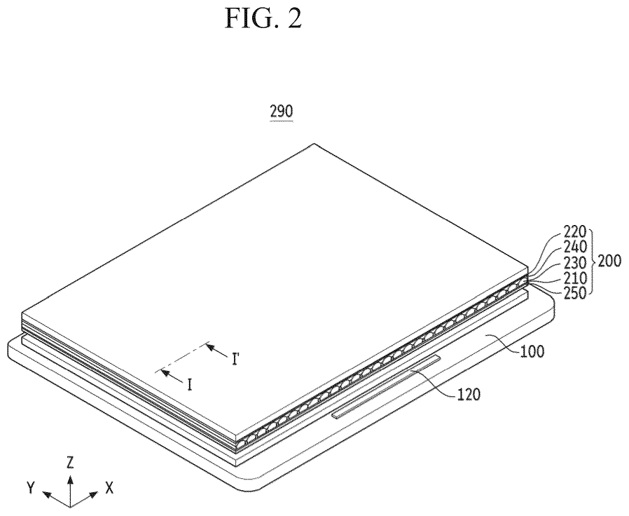

FIG. 1 is an exploded perspective view illustrating a display device according to an embodiment of the present disclosure. FIG. 2 is a perspective view of the display device illustrated in FIG. 1.

A display device 290 may be implemented as a flat panel display device such as, for example, a liquid crystal display (LCD), a field emission display (FED), a plasma display panel (PDP), and an organic light emitting diode (OLED) display.

The display device 290 may be a stereoscopic image display device including a display module 100 and an optical member 200, for example, a three-dimensional (3D) image display device. In order to display a 3D image, the stereoscopic image display device may separate and display a left-eye image and a right-eye image in a front surface direction so as to make a viewer feel a three-dimensional effect by binocular parallax. Furthermore, the stereoscopic image display device may separate and provide a plurality of viewing angle images to a front surface of the display device so that different images are viewed for each of different viewing angles.

The display device 290 according to an embodiment may be a light field display that allows different image information to be viewed to both eyes of the viewer by including the optical member 200 disposed on a front surface of the display module 100. The light field display may form a light field and generate a 3D stereoscopic image by using the display module 100 displaying a two-dimensional (2D) image and the optical member 200 converting the 2D image into a 3D image and displaying the 3D image. As described further below, the light field display allows image display light generated from each pixel of the display module 100 to form a light field directed in a specific direction (a specific viewing angle and/or a specific point of view) by a stereoscopic lens, a pinhole, a barrier, or the like, included in the optical member 200. Accordingly, 3D stereoscopic image information corresponding to the specific direction may be provided to the viewer.

The display module 100 may include a display panel 110 and a display driver 120. The display module 100 may also be referred to as a display device.

The display panel 110 may include a display area DA and a non-display area NDA. The display area DA may include data lines, scan lines, voltage supply lines, and a plurality of pixels connected to the corresponding data lines and scan lines. For example, the scan lines may extend in a first direction (e.g., an X-axis direction) and may be spaced apart from each other in a second direction (e.g., a Y-axis direction). The data lines and the voltage supply lines may extend in the second direction (e.g., the Y-axis direction) and may be spaced apart from each other in the first direction (e.g., the X-axis direction).

Each pixel (or unit pixel) formed and arranged in the display panel 110 includes a minimum number of sub-pixels capable of displaying white. For example, each pixel may include three sub-pixels respectively displaying red light, green light, and blue light. Each of the sub-pixels that are alternately arranged may be connected to at least one scan line, data line, and power supply line. Each of the sub-pixels may include thin-film transistors including a driving transistor and at least one switching transistor, a light-emitting element, and a capacitor. Each of the pixels may receive a data voltage of the data line when a scan signal is applied from the scan line to each of the pixels, and may emit light by supplying a driving current to the light-emitting element according to the data voltage applied to a gate electrode.

In the present disclosure, the pixels (e.g., the respective unit pixels) of the display panel 110 display a two-dimensional multi-view image according to image data supply order of the display driver 120. The multi-view image includes n view images (here, n is a positive integer of 2 or more). Here, the n view images are images generated by capturing an image of a specific object (or content) with n cameras spaced apart from each other by a binocular distance of an ordinary person.

For example, the n view images may include first data derived by collecting the specific content from a first viewing angle, second data derived by collecting the specific content from a second viewing angle, . . . , n-th data derived by collecting the specific content from an n-th viewing angle, and the like. A plurality of data (first data to n-th data) generated by capturing images of the specific content may be digital data.

The display panel 110 may display the multi-view image in units of n pixels during an image display period. For example, the display panel 110 may display the multi-view image in units of two pixels. That is, two pixels of the display panel 110 may display the multi-view image including two view images. For example, the display panel 110 may display the multi-view image in units of time-division frame (or sub-frame) periods according to time-division driving of the display driver 120. In this case, the display panel 110 may display the multi-view image in units of two pixels for each time-division frame period. The time-division frame period is a period in which one frame period is divided and driven in units of ½ or ⅓ frame periods.

In this manner, the arrangement of pixels to output multiple views and the selective mapping of sub-pixels to different view images establishes the basis for applying region-specific refractive control in subsequent stages of the optical path. When a given region of the display panel is intended to present a 2D image, the sub-pixels corresponding to multiple views can be driven with identical image data, thereby forming a higher resolution composite image. Conversely, when the same region is intended to present a 3D image, the sub-pixels are driven with distinct view images, and the later-described optical member 200 can be configured to refract or not refract light from these sub-pixels to direct each view toward its intended viewing zone. This coordinated relationship between multi-view pixel mapping and refractive control may provide improved hybrid 2D/3D operation of the display device.

The non-display area NDA may surround the display area DA at an edge of the display panel 110. The non-display area NDA may include a scan driver applying scan signals to the scan lines and pads connected to the display driver 120. For example, the display driver 120 may be disposed on one side of the non-display area NDA, and the pads may be disposed at an edge of one side of the non-display area NDA on which the display driver 120 is disposed.

The display driver 120 may output control signals and image data voltages for driving the display panel 110 in units of at least one frame or units of at least one time-division frame (subframe). For example, the display driver 120 may supply image data voltages to the data lines in units of at least one time-division frame (subframe). The display driver 120 may supply a source voltage to the power supply line and supply scan control signals to the scan driver. The image data voltage may include a plurality of data voltages supplied to a plurality of pixels (or sub-pixels) connected to a plurality of data lines.

The optical member 200 includes an optical lens unit 230 (e.g., a refractive index anisotropic lens) formed between first and second base substrates 210 and 220, a polarization control unit 250 formed to overlap the optical lens unit 230, and a filler layer 240 filled between the optical lens unit 230 and the second base substrate 220.

In an embodiment, the optical lens unit 230 and the filler layer 240 may cooperate to implement controlled refraction without introducing excessive optical loss or crosstalk between adjacent views. The filler layer 240 can be selected to have a refractive index that, when combined with the refractive index of the optical lens unit 230 in its non-refracting state, substantially matches that of the surrounding medium, thereby allowing 2D images to pass through with minimal/reduced distortion. In the refracting state, differences in refractive index between the optical lens unit 230 and the filler layer 240 may cause light rays from different sub-pixels to be deflected toward separate viewing zones, thereby supporting the multi-view 3D mode.

The display driver 120 may be formed as an integrated circuit (IC) and disposed in the non-display area NDA of the display panel 110 in, for example, a chip on glass (COG) manner, a chip on plastic (COP) manner, or an ultrasonic bonding manner. In an embodiment, the display driver 120 may be mounted on a circuit board and connected to the pads of the display panel 110.

The optical member 200 may be disposed in a front surface direction of the display panel 110 or the display module 100. The optical member 200 may be attached to one surface of the display panel 110 or the display area DA through an adhesive member. Such an optical member 200 may be bonded to the front surface of the display module 100 by a separate panel bonding device.

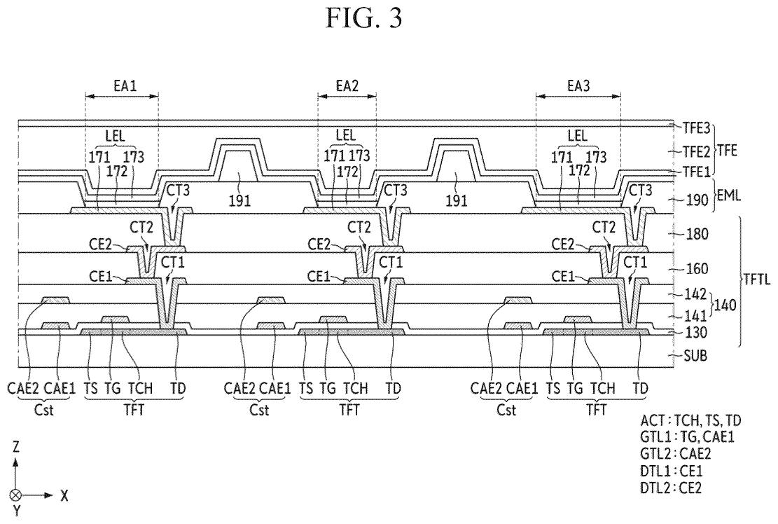

FIG. 3 is a cross-sectional view illustrating a portion of the display device including emission areas.

Referring to FIG. 3, the display panel 110 may include a substrate SUB, a thin-film transistor layer TFTL, a light-emitting element layer EML, and an encapsulation film TFE.

The thin-film transistor layer TFTL may include an active layer ACT, a first gate metal layer GTL1, a second gate metal layer GTL2, a first data metal layer DTL1, and a second data metal layer DTL2. In addition, the thin-film transistor layer TFTL may include a buffer layer, a gate insulating film 130, a first interlayer insulating film 141, a second interlayer insulating film 142, a first planarization film 160, and a second planarization film 180. The thin-film transistor layer TFTL includes a plurality of thin-film transistors TFT, and each of the plurality of thin-film transistors TFT may include a channel TCH, a gate electrode TG, a first electrode TS, and a second electrode TD.

The active layer ACT may be disposed on the substrate SUB. The active layer ACT may include a silicon semiconductor such as polycrystalline silicon, single crystal silicon, and low-temperature polycrystalline silicon or include an oxide semiconductor.

The active layer ACT may include the channel TCH, the first electrode TS, and the second electrode TD of each of the plurality of thin-film transistors TFT. The channel TCH may be a region overlapping the gate electrode TG of the thin-film transistor TFT in a third direction (e.g., a Z-axis direction), which is a thickness direction of the substrate SUB. The first electrode TS may be disposed on one side of the channel TCH, and the second electrode TD may be disposed on the other side of the channel TCH. The first electrode TS and the second electrode TD may be regions that do not overlap the gate electrode TG in the third direction (e.g., the Z-axis direction). The first electrode TS and the second electrode TD may be regions having conductivity by doping a silicon semiconductor or an oxide semiconductor with ions.

The gate insulating film 130 may be disposed on the active layer ACT. The gate insulating film 130 may be formed as an inorganic film such as, for example, a silicon nitride layer, a silicon oxynitride layer, a silicon oxide layer, a titanium oxide layer, or an aluminum oxide layer.

The first gate metal layer GTL1 may be disposed on the gate insulating film 130. The first gate metal layer GTL1 may include the gate electrode TG of each of the plurality of thin-film transistors TFT and a first capacitor electrode CAE1. The first gate metal layer GTL1 may be formed as a single layer or multiple layers made of any one of, for example, molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the first gate metal layer GTL1. The first interlayer insulating film 141 may be formed as an inorganic film such as, for example, a silicon nitride layer, a silicon oxynitride layer, a silicon oxide layer, a titanium oxide layer, or an aluminum oxide layer.

The second gate metal layer GTL2 may be disposed on the first interlayer insulating film 141. The second gate metal layer GTL2 may include a second capacitor electrode CAE2. The second capacitor electrode CAE2 may overlap the first capacitor electrode CAE1 in the third direction (e.g., the Z-axis direction). A capacitor Cst may include the first capacitor electrode CAE1 and the second capacitor electrode CAE2. The second gate metal layer GTL2 may be formed as a single layer or multiple layers made of any one of, for example, molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the second gate metal layer GTL2. The second interlayer insulating film 142 may be formed as an inorganic film such as, for example, a silicon nitride layer, a silicon oxynitride layer, a silicon oxide layer, a titanium oxide layer, or an aluminum oxide layer.

The first data metal layer DTL1 including a first connection electrode CE1 may be disposed on the second interlayer insulating film 142. The first connection electrode CE1 may be connected to the first electrode TS or the second electrode TD of the thin-film transistor TFT through a first contact hole CT1 penetrating through the gate insulating film 130, the first interlayer insulating film 141, and the second interlayer insulating film 142. The first data metal layer DTL1 may be formed as a single layer or multiple layers made of any one of, for example, molybdenum (Mo), aluminum (Al), chromium (Cr), gold (Au), titanium (Ti), nickel (Ni), neodymium (Nd), and copper (Cu), or alloys thereof.

The first planarization film 160 for planarizing a step due to the active layer ACT, the first gate metal layer GTL1, the second gate metal layer GTL2, and the first data metal layer DTL1 may be disposed on the first data metal layer DTL1. The first planarization film 160 may be formed as an organic film made of, for example, an acrylic resin, an epoxy resin, a phenolic resin, a polyamide resin, a polyimide resin, or the like.

The second data metal layer DTL2 may be disposed on the first planarization film 160. The second data metal layer DTL2 may include a second connection electrode CE2. The second connection electrode CE2 may be connected to the first connection electrode CE1 through a second contact hole CT2 penetrating through the first planarization layer film 160. The second data metal layer DTL2 may be formed as a single layer or multiple layers made of any one of, for example, molybdenum (Mo), aluminum (Al), chromium (Cr), gold (Au), titanium (Ti), nickel (Ni), neodymium (Nd), and copper (Cu), or alloys thereof.

The second planarization film 180 may be disposed on the second data metal layer DTL2. The second planarization film 180 may be formed as an organic film made of, for example, an acrylic resin, an epoxy resin, a phenolic resin, a polyamide resin, a polyimide resin, or the like.

The light-emitting element layer EML may be disposed on the second planarization film 180. The light-emitting element layer EML may include a plurality of light-emitting elements LEL and a pixel defining film 190. Each of the plurality of light-emitting elements LEL may be an organic light emitting diode element including a pixel electrode 171, a light-emitting layer 172, and a common electrode 173, but embodiments of the present disclosure are not limited thereto.

The pixel electrode 171 may be disposed on the second planarization film 180. The pixel electrode 171 may be connected to the second connection electrode CE2 through a third connection hole CT3 penetrating through the second planarization film 180.

In a top emission structure in which light is emitted toward the common electrode 173 based on the light-emitting layer 172, the pixel electrode 171 may be made of a metal material having high reflectivity, such as, for example, a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The pixel defining film 190 may cover an edge of each of the pixel electrodes 171 on the second planarization film 180 in order to define a plurality of emission areas EA1, EA2, and EA3. The pixel defining film 190 may be formed as an organic film made of, for example, an acrylic resin, an epoxy resin, a phenolic resin, a polyamide resin, a polyimide resin, or the like.

Each of the plurality of emission areas EA1, EA2, and EA3 refers to an area where the pixel electrode 171, the light-emitting layer 172, and the common electrode 173 are sequentially stacked and holes from the pixel electrode 171 and electrons from the common electrode 173 are combined with each other in the light-emitting layer 172 to emit light.

The light-emitting layer 172 may be disposed on the pixel electrode 171. The light-emitting layer 172 may include an organic material to emit light of a selected color. For example, the light-emitting layer 172 may include a hole transporting layer, an organic material layer, and an electron transporting layer.

The common electrode 173 may be disposed on the light-emitting layer 172. The common electrode 173 may cover the light-emitting layer 172. The common electrode 173 may be a common layer formed in common in the plurality of emission areas EA1, EA2, and EA3. A capping layer may be formed on the common electrode 173.

In the top emission structure, the common electrode 173 may be made of a transparent conductive material (TCO) such as, for example, ITO or indium zinc oxide (IZO) capable of transmitting light or a semi-transmissive conductive material such as magnesium (Mg), silver (Ag), or an alloy of magnesium (Mg) and silver (Ag). When the common electrode 173 is made of the semi-transmissive conductive material, light emission efficiency may be increased by a micro cavity.

A spacer 191 may be disposed on the pixel defining film 190. The spacer 191 may serve to support a mask during a process of manufacturing the light-emitting layer 172. The spacer 191 may be formed as an organic film made of, for example, an acrylic resin, an epoxy resin, a phenolic resin, a polyamide resin, a polyimide resin, or the like.

The encapsulation film TFE may be disposed on the common electrode 173. The encapsulation film TFE may include at least one inorganic film in order to prevent oxygen or moisture from permeating into the light-emitting element layer EML. In addition, the encapsulation film TFE may include at least one organic film in order to protect the light-emitting element layer EML from foreign substances such as dust. For example, the encapsulation film TFE may include a first encapsulation inorganic film TFE1, an encapsulation organic film TFE2, and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. Each of the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of, for example, an acrylic resin, an epoxy resin, a phenolic resin, a polyamide resin, a polyimide resin, or the like.

As illustrated in FIG. 3, as an example, a third emission area EA3 is greater than a first emission area EA1, and the first emission area EA1 is greater than a second emission area EA2. Here, the first emission area EA1 may be a red emission area, the second emission area EA2 may be a green emission area, and the third emission area EA3 may be a blue emission area. However, embodiments of the present disclosure are not limited to relative sizes of the emission areas.

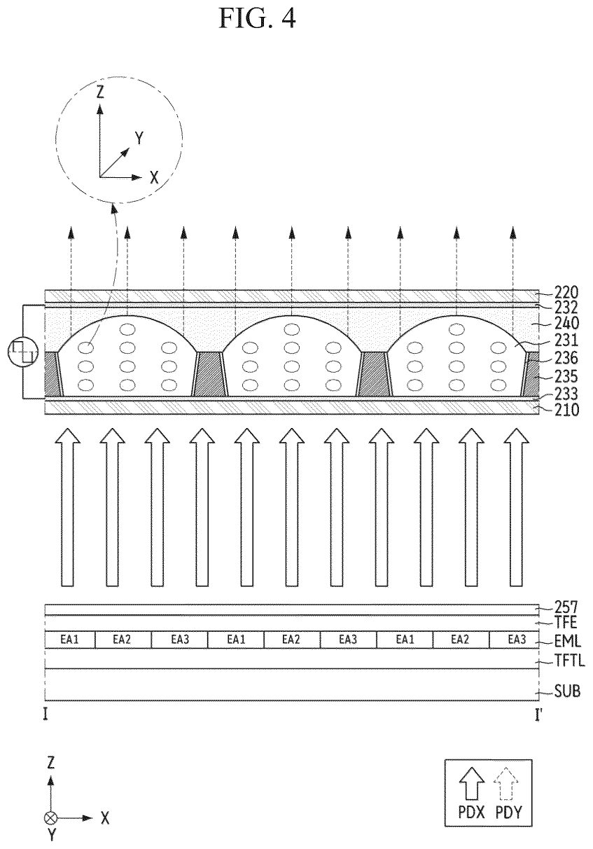

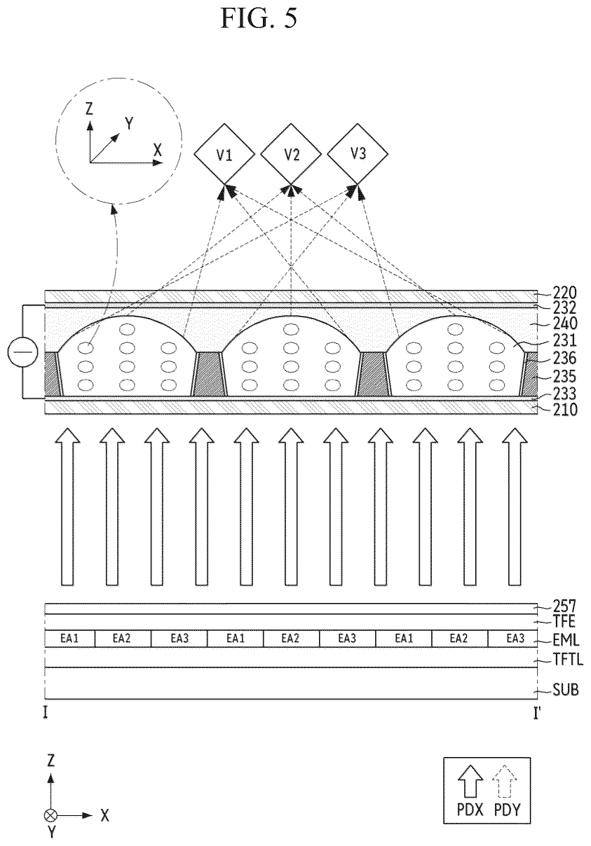

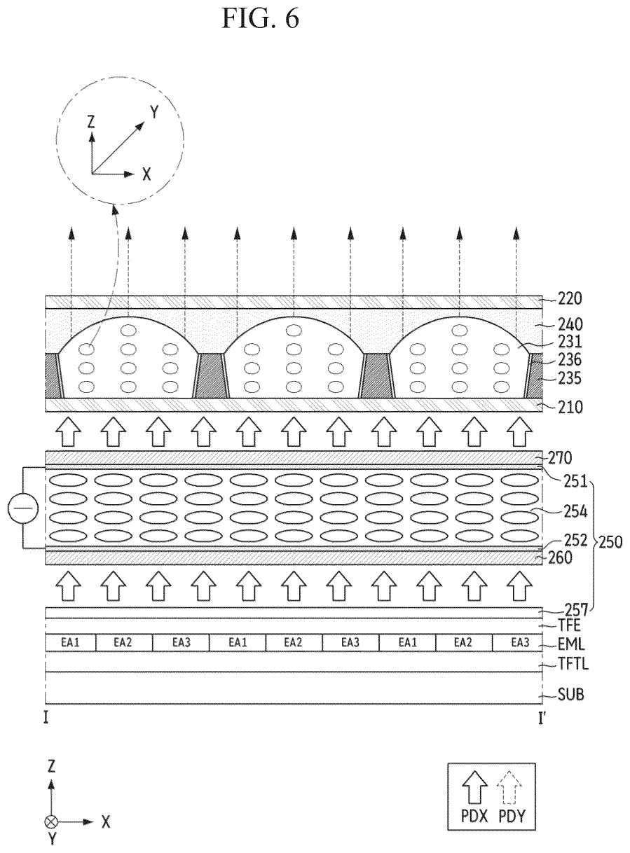

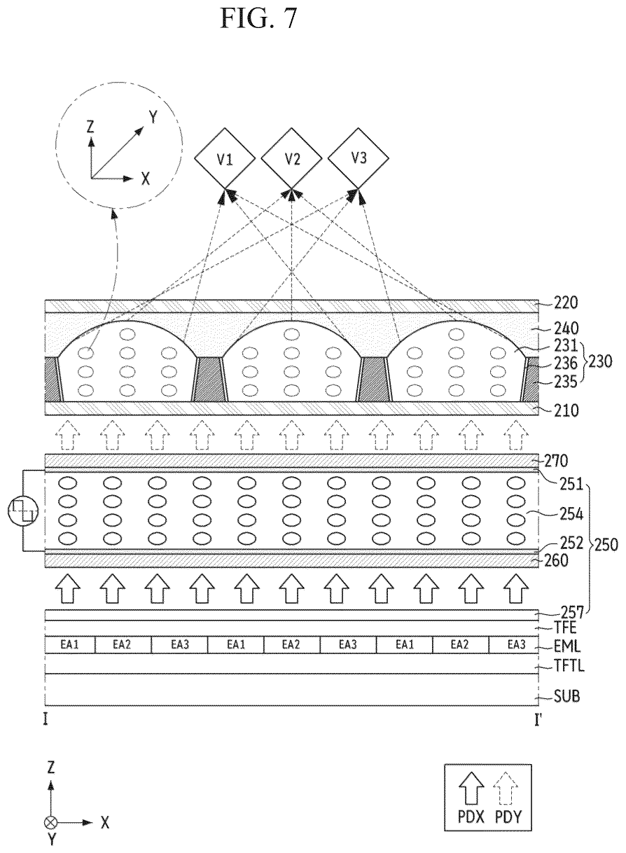

FIG. 4 is a cross-sectional view illustrating a first type of light field display in which a two-dimensional image is implemented. FIG. 5 is a cross-sectional view illustrating the first type of light field display in which a three-dimensional image is implemented. FIG. 6 is a cross-sectional view illustrating a second type of light field display in which a two-dimensional image is implemented. FIG. 7 is a cross-sectional view illustrating the second type of light field display in which a three-dimensional image is implemented.

The light field display may allow different image information to be viewed to both eyes of the viewer by including the optical member disposed on the front surface of the display module, as described above. The light field display may implement a two-dimensional image or a three-dimensional image.

A specific content may include not only all things that exist in the real world, such as texts, pictures, things, and objects, but also all things that are implemented as digital data and do not exist in the real world. First data may be derived by collecting the specific content from a first viewing angle. Second data may be derived by collecting the specific content from a second viewing angle. Furthermore, n-th data may be derived when the specific content is collected from an n-th viewing angle.

The display device according to an embodiment may include a display panel in which a plurality of light-emitting elements and an optical member are disposed on the display panel. Light emitted from any light-emitting element disposed in the display panel may or may not be refracted while passing through the optical member depending on whether a 3D image is implemented. For example, when the 3D image is to be implemented, the light emitted from any light-emitting element may be refracted in the optical member. For example, when a 2D image is to be implemented, the light emitted from any light-emitting element may not be refracted in the optical member.

However, even when the 2D image is to be implemented, the light emitted from any light-emitting element may be refracted, and in this case, decreased display resolution may occur.

In the absence of such control, 2D image regions subject to refractive lensing can suffer from apparent resolution degradation because multiple sub-pixels intended to form a single composite pixel are optically displaced relative to one another. This displacement may reduce effective pixel density in the perceived image and can produce blurring or aliasing. By integrating a polarization control unit 250 in the optical stack, the display device according to embodiments can selectively prevent light from being refracted in designated 2D regions while still allowing refracted light in 3D regions. This targeted refractive control allows hybrid 2D/3D images to be displayed without sacrificing resolution quality in the 2D portions.

A viewing angle may be assigned to each of the plurality of light-emitting elements by adjusting refraction directions of light emitted from the plurality of light-emitting elements. This may be referred to as viewing angle mapping. In order to adjust the directions of the light emitted from the light-emitting elements, a pitch, a tilt angle, and the like, of lenses (e.g., slanted lenses) included in the optical member may be adjusted.

A specific viewing angle may be mapped to each of the plurality of light-emitting elements, and light emitted from the light-emitting element to which the specific viewing angle is mapped may travel in a direction of the assigned viewing angle. For example, light emitted from a light-emitting element to which the first viewing angle is mapped may travel in a direction of the first viewing angle where a first view area is disposed, and light emitted from a light-emitting element to which the second viewing angle is mapped may travel in a direction of the second viewing angle where a second view area is disposed.

The first data derived by collecting the specific content from the first viewing angle may be input to the light-emitting element to which the first viewing angle is mapped. The second data may be input to the light-emitting element to which the second viewing angle is mapped.

The first viewing angle may be disposed on one side (e.g., the left eye side) based on the center of both eyes of a user. The second viewing angle may be disposed on the other side (e.g., the right eye side) based on the center of both eyes of the user.

When different images are perceived by the user's left and right eyes regardless of which viewing angle is mapped, the user may experience that a three-dimensional image is implemented from the display device. When the same image is perceived by the user's left and right eyes, the user may experience that a two-dimensional image is implemented from the display device. A case where the same image is perceived by the user's left and right eyes may be a case where light emitted from the display panel is not refracted. However, as described above, even though the light emitted from the display panel is refracted, the same image may be perceived by the user's left and right eyes, and in this case, decreased display resolution may occur.

Accordingly, the user may experience a three-dimensional image from an image implemented by inputting the first data to the light-emitting element to which the first viewing angle is mapped and inputting the second data to the light-emitting element to which the second viewing angle is mapped.

In an embodiment, the user may experience a two-dimensional image from an image implemented by inputting the first data to both the light-emitting element to which the first viewing angle is mapped and the light-emitting element to which the second viewing angle is mapped. The light emitted from the light-emitting element to which the first viewing angle is mapped is still refracted even when the two-dimensional image is implemented, and the light emitted from the light-emitting element to which the second viewing angle is mapped is also still refracted.

In an embodiment, the two-dimensional image may be implemented even when the light emitted from the light-emitting element is not refracted in the optical member. In this case, any light emitted from the light-emitting element is not refracted regardless of the viewing angle mapped to the light-emitting element, and thus, the user may experience the two-dimensional image. A resolution of the two-dimensional image implemented as described above may be relatively greater than a resolution of the two-dimensional image implemented when the light is refracted but the same image is perceived by the user's left and right eyes.

That is, the two-dimensional image may be implemented in a case where the light emitted from the light-emitting element is not refracted in the optical member or in a case where the same data is input to both eyes of the user even though the light emitted from the light-emitting element is refracted. In addition, resolutions of the two-dimensional images in each case may be different from each other.

The light field display may include a switchable display device that may determine whether to implement the two-dimensional image or the three-dimensional image by adjusting whether the light emitted from the display panel is refracted and a non-switchable display device in which the light emitted from the display panel is always refracted. Even in a case of the non-switchable display device in which the light emitted from the display panel is always refracted, the two-dimensional image may be implemented when the same data is input regardless of the viewing angle mapped to the light-emitting element as described above. When the two-dimensional image is implemented in the non-switchable display device, a resolution decrease problem may occur.

The switchable display device may determine whether to implement the two-dimensional image or the three-dimensional image by adjusting a linear polarization direction of the light emitted from the display panel and utilizing refractive index anisotropy of lenses included in the optical lens unit.

For example, the light emitted from the display panel may pass through a polarizing member disposed above the display panel and be then output to a path in a first linear polarization direction.

In an embodiment, a minor axis direction of the lens included in the optical lens unit may coincide with the first linear polarization direction. A major axis direction of the lens may coincide with a second linear polarization direction.

The optical lens unit may further include a filler layer disposed on a plurality of lenses. The plurality of lenses may have birefringence characteristics. For example, a refractive index of the lens in the minor axis direction may be the same as a refractive index of the filler layer, and a refractive index of the lens in the major axis direction may be greater than the refractive index of the filler layer. However, embodiments of the present disclosure are not limited thereto.

In the case described above, when a voltage is applied to the lens, the minor axis direction of the lens may be parallel to the path in the first linear polarization direction. When the light having the path in the first linear polarization direction and emitted from the display panel passes through the lens, the light may experience the refractive index in the minor axis direction coinciding with the first linear polarization direction. Since the refractive index of the lens in the minor axis direction is the same as the refractive index of the filler layer, the light passing through the lens may travel straight without being refracted at an interface between the lens and the filler layer. In this case, since the light is not refracted, light perceived by both eyes of the user may be the straight traveling light, and the user may experience that the two-dimensional image is implemented. Such a mechanism may be applied to the first type of light field display in which the two-dimensional image is implemented (see FIG. 4).

In an embodiment, in the first type switchable light field display, the refractive index anisotropy of the driving liquid crystal 254 allows the optical lens unit 230 to alternate between refracting and non-refracting states based on applied driving voltages to the first driving electrode 251 and the second driving electrode 252. This “on-demand” refracting capability may enable a given region of the display to be dynamically assigned as a 2D or 3D region without physical changes to the optical lens unit 230, thereby improving operational flexibility and enabling rapid mode changes in response to displayed content.

In the case described above, when a voltage is not applied to the lens, the major axis direction of the lens may be parallel to the path in the first linear polarization direction. When the light having the path in the first linear polarization direction and emitted from the display panel passes through the lens, the light may experience the refractive index of the lens in the major axis direction coinciding with the first linear polarization direction. Since the refractive index of the lens in the major axis direction is greater than the refractive index of the filler layer, the light passing through the lens may be refracted at the interface between the lens and the filler layer. In this case, since the light is refracted, light perceived by both eyes of the user may be the refracted light, and the user may experience that the three-dimensional image is implemented. Such a mechanism may be applied to the first type of light field display in which the three-dimensional image is implemented (see FIG. 5).

In the second type of light field display, a voltage may not be applied to the lens, and the minor axis direction and the major axis direction of the lens may be fixed to be parallel to the first linear polarization direction and the second linear polarization direction, respectively (see FIGS. 6 and 7). Instead, the light having the path in the first linear polarization direction and emitted from the display panel may pass through a separate driving liquid crystal disposed between driving electrodes. Light passing through the driving liquid crystal to which a voltage is not applied may pass through the driving liquid crystal while being maintained at the path in the first linear polarization direction (see FIG. 6). Light passing through the driving liquid crystal to which a voltage is applied may pass through the driving liquid crystal while being switched from the path in the first linear polarization direction to a path in the second linear polarization direction (see FIG. 7).

Since the minor axis direction and the major axis direction of the lens are parallel to the first linear polarization direction and the second linear polarization direction, respectively, when the light passing through the driving liquid crystal has the path in the first linear polarization direction, the light may experience the refractive index of the lens in the minor axis direction. When the light passing through the driving liquid crystal has the path in the second linear polarization direction, the light may experience the refractive index of the lens in the major axis direction. Since the refractive index of the lens in the minor axis direction is the same as the refractive index of the filler layer and the refractive index of the lens in the major axis direction is greater than the refractive index of the filler layer, it may be determined whether the light passing through the driving liquid crystal is refracted at the interface between the lens and the filler layer according to the linear polarization direction of light passing through the driving liquid crystal.

In an embodiment, in the second type switchable light field display, the polarization control unit 250 is positioned such that it modulates the polarization state of light before the light enters the optical lens unit 230. This configuration may allow the refractive behavior of the optical lens unit 230 to be controlled without altering its refractive axis, in contrast to the first type. As a result, the second type may achieve faster switching speeds and reduced optical stress on the driving liquid crystal 254.

As described above, the switchable light field display may include the first type of light field display (see FIGS. 4 and 5) and the second type of light field display (see FIGS. 6 and 7).

In the first type of light field display, as described above, the linear polarization direction of the light passing through the display panel is not changed. Instead, the first type of light field display may directly change the major axis direction and the minor axis direction of the lens having the birefringence characteristic. Any changed axis direction coincides with the linear polarization direction of the light passing through the display panel, and the light may pass through the interface while experiencing the refractive index of the lens in any changed axis direction.

In the second type of light field display, the linear polarization direction of the light passing through the display panel may be changed while passing through the driving liquid crystal. Instead, the second type of light field display may not directly change the major axis direction and the minor axis direction of the lens having the birefringence characteristic. Accordingly, the linear polarization direction of the light passing through the driving liquid crystal coincides with a fixed axis direction of the lens, and the light may pass through the interface while experiencing a refractive index of the lens in the fixed axis direction.

Referring to FIGS. 6 and 7, in the second type of light field display, the display panel may include a substrate SUB, a thin-film transistor layer TFTL, a light-emitting element layer EML, and an encapsulation film TFE.

The substrate SUB may have rigidity so as to support an element formed on the substrate SUB. For example, the substrate SUB may be a glass substrate or a plastic substrate such as a polyethylene terephthalate (PET) substrate.

The thin-film transistor layer TFTL may be disposed on the substrate SUB. The thin-film transistor layer TFTL may adjust brightness of the display device 290. The thin-film transistor layer TFTL may include transistors.

The light-emitting element layer EML may be disposed on the thin-film transistor layer TFTL. The light-emitting element layer EML may include first to third emission areas EA1, EA2, and EA3. The first to third emission areas EA1, EA2, and EA3 may be alternately disposed.

The encapsulation film TFE may be disposed on the light-emitting element layer EML. The encapsulation film TFEL may include at least one inorganic film and at least one organic film for encapsulating the light-emitting element layer.

The optical member may include an optical lens unit disposed between a first base substrate 210 and a second base substrate 220. The optical lens unit may include a plurality of lenses 231 and a black matrix 235, a light reflecting portion 236, and the like, disposed between the plurality of lenses 231. The optical member may include a filler layer 240 disposed between the first base substrate 210 and the second base substrate 220. It has been illustrated in FIGS. 6 and 7 that the filler layer 240 is disposed on the optical lens unit, but embodiments of the present disclosure are not limited thereto. For example, light passing through the display panel may first pass through the filler layer 240 and then pass through the optical lens unit. In addition, the lens 231 in the optical lens unit is convex in the third direction (e.g., in the Z-axis direction), but embodiments of the present disclosure are not limited thereto.

As described above, since a refractive index range of a material having refractive index anisotropy in the lens 231 and a refractive index value of the filler layer 240 are adjusted and it is determined by the presence or absence of a difference in refractive index whether the light is refracted, an upper and lower relationship between the optical lens unit and the filler layer 240, a convex direction of the lens 231, and the like, may be efficiently designed.

Each of the first base substrate 210, the second base substrate 220, a third base substrate 260, and a fourth base substrate 270 may include a material through which light may be transmitted, such as, for example, glass or plastic.

A polarization control unit 250 switching and outputting 2D image display light of the display panel into a path PDX in the first linear polarization direction or a path PDY in the second linear polarization direction may be formed on a rear surface of the first base substrate 210 or a front surface of the display panel. The polarization control unit 250 may include a first driving electrode 251, a second driving electrode 252, and driving liquid crystals 254 disposed between the first driving electrode 251 and the second driving electrode 252. The polarization control unit 250 may further include a polarizing member 257 disposed on the display panel.

The polarization control unit 250 may allow light incident on the path PDX in the first linear polarization direction through the polarizing member 257 to be maintained at and pass through the path PDX in the first linear polarization direction or to be switched to and pass through the path PDY in the second linear polarization direction.

The polarization control unit 250 may allow the light incident on the path PDX in the first linear polarization direction through the polarizing member 257 to be switched to and pass through a path in any linear polarization direction between the first linear polarization direction and the second linear polarization direction.

For example, the first linear polarization direction may be parallel to the first direction (e.g., the X-axis direction) and the second linear polarization direction may be parallel to the second direction (e.g., the Y-axis direction), but embodiments of the present disclosure are not limited thereto.

At least some components 251, 252, and 254 of the polarization control unit 250 may be disposed between the third base substrate 260 and the fourth base substrate 270. The other component 257 of the polarization control unit 250 may be disposed between the display panel and the third base substrate 260.

The first driving electrode 251 may be disposed between the third base substrate 260 and the fourth base substrate 270. A voltage may be applied to the first driving electrode 251.

The second driving electrode 252 may be disposed between the third base substrate 260 and the first driving electrode 251. The second driving electrode 252 may be parallel to the first driving electrode 251. A shape of the second driving electrode 252 may correspond to a shape of the first driving electrode 251. A voltage may be applied to the second driving electrode 252. The driving liquid crystals 254 may adjust a linear polarization direction of light by a difference between the voltage applied to the first driving electrode 251 and the voltage applied to the second driving electrode 252.

The polarizing member 257 may be disposed between the display panel and the third base substrate 260. The light emitted from the display panel may vibrate in all directions. The polarizing member 257 may pass only light vibrating in a specific direction among the light emitted from the display panel and block the other light. In an embodiment, the polarizing member 257 may pass only light having the path PDX in the first linear polarization direction among the light emitted from the display panel, but embodiments of the present disclosure are not limited thereto.

The driving liquid crystals 254 may be disposed between the first driving electrode 251 and the second driving electrode 252. The driving liquid crystal 254 may include a liquid crystal that is a birefringent material. An arrangement of the driving liquid crystals 254 may be changed depending on the difference between the voltages applied to the first driving electrode 251 and the second driving electrode 252. The driving liquid crystal 254 may be a twisted nematic (TN) liquid crystal.

Referring to FIG. 6, a difference between the voltage applied to the first driving electrode 251 and the voltage applied to the second driving electrode 252 during a two-dimensional image display period may be a selected value or less. The driving liquid crystal 254 may maintain the linear polarization direction of the light incident with the path PDX in the first linear polarization direction. The light passing through the driving liquid crystal 254 may still have the path PDX in the first linear polarization direction.

Referring to FIG. 7, a difference between the voltage applied to the first driving electrode 251 and the voltage applied to the second driving electrode 252 during a three-dimensional image display period may be a selected value or more. The driving liquid crystal 254 may switch the linear polarization direction of the light incident with the path PDX in the first linear polarization direction. The light passing through the driving liquid crystal 254 may have the path PDY in the second linear polarization direction.

Referring to FIGS. 6 and 7, the first base substrate 210, the second base substrate 220, and the optical lens units disposed between the first base substrate 210 and the second base substrate 220 may be disposed on the fourth base substrate 270. The optical lens units may be arranged in parallel and formed in the shape of a lens sheet. The polarization control unit 250 may be disposed in a state in which it is stacked to overlap the optical lens unit formed in the shape of the lens sheet.

The optical lens unit may include the plurality of lenses 231, the black matrix 235, and the light reflecting portion 236.

Light passing through the plurality of lenses 231 may experience a refractive index of the lens 231 in the major axis direction, a refractive index of the lens 231 in the minor axis direction, or innumerable refractive indices of the lens 231 in a direction between the major axis direction and the minor axis direction according to an arrangement of birefringent materials (e.g., liquid crystals, slits, etc.) included in the plurality of lenses 231. The innumerable refractive indices of the lens 231 in the direction between the major axis direction and the minor axis direction may be smaller than the refractive index of the lens 231 in the major axis direction and greater than the refractive index of the lens 231 in the minor axis direction, but embodiments of the present disclosure are not limited thereto. For example, the innumerable refractive indices of the lens 231 in the direction between the major axis direction and the minor axis direction may be smaller than the refractive index of the lens 231 in the minor axis direction and greater than the refractive index of the lens 231 in the major axis direction.

In an embodiment, the major axis direction of the lens 231 may be parallel to the second direction (e.g., the Y-axis direction), and the minor axis direction of the lens 231 may be parallel to the first direction (e.g., the X-axis direction). In addition, a refractive index of the filler layer 240 disposed on the lens 231 may be the same as the refractive index of the lens 231 in the minor axis direction and smaller than the refractive index the lens 231 in the major axis direction, but embodiments of the present disclosure are not limited thereto.

Referring to FIG. 6, light passing through the driving liquid crystal 254 may have the path PDX in the first linear polarization direction, and the first linear polarization direction may coincide with or be parallel to the first direction (e.g., the X-axis direction). Accordingly, the light passing through the driving liquid crystal 254 may experience the refractive index of the lens 231 in the minor axis direction. Since the refractive index of the lens 231 in the minor axis direction is the same as the refractive index of the filler layer 240, the light passing through the driving liquid crystal 254 may travel straight without being refracted at the interface between the lens 231 and the filler layer 240. The two-dimensional image may be implemented from the second type of light field display by the light that is not refracted.

Referring to FIG. 7, light passing through the driving liquid crystal 254 may have the path PDY in the second linear polarization direction, and the second linear polarization direction may coincide with or be parallel to the second direction (e.g., the Y-axis direction). Accordingly, the light passing through the driving liquid crystal 254 may experience the refractive index of the lens 231 in the major axis direction. Since the refractive index of the lens 231 in the major axis direction is greater than the refractive index of the filler layer 240, the light passing through the driving liquid crystal 254 may be refracted at the interface between the lens 231 and the filler layer 240. The three-dimensional image may be implemented from the second type of light field display by the refracted light. The refracted light may move toward a first view area V1, a second view area V2, and a third view area V3 according to mapped viewing angles.

Still referring to FIGS. 6 and 7, the black matrix 235 may be disposed between the plurality of lenses 231. The black matrix 235 may include a light absorbing material absorbing light. As an example, the light absorbing material may be a black dye or a black pigment. The black matrix 235 may absorb the light between the plurality of lenses 231. Accordingly, the black matrix 235 may prevent crosstalk from occurring due to diffraction of light at a boundary portion between the plurality of lenses 231.

In an embodiment, the black matrix 235 and the light reflecting portion 236 may cooperate to preserve image separation and contrast in both 2D and 3D modes. In 3D operation, the black matrix 235 can block stray light that might otherwise leak between adjacent views, while the light reflecting portion 236 can redirect unused light toward active emission areas to enhance brightness. In 2D operation, these elements may help maintain sharpness and uniformity by reducing parasitic light paths that could reduce contrast.

In a plan view, a length of a lower surface of the black matrix 235 may be greater than a length of an upper surface of the black matrix 235. Side surfaces of the black matrix 235 may be formed as planes. That is, the black matrix 235 may be formed in a trapezoidal shape.

The light reflecting portion 236 may be disposed between the plurality of lenses 231 and the black matrix 235 in order to reflect light traveling from the emission areas EA1, EA2, and EA3 toward the black matrix 235.

The filler layer 240 may be disposed on the plurality of lenses 231, the black matrix 235, and the light reflecting portion 236. The second base substrate 220 may be disposed on the filler layer 240.

The filler layer 240 may include a transparent material through which light may be transmitted. As an example, the filler layer 240 may include an isotropic polymer material.

The refractive index of the filler layer 240 may be the same as a refractive index, in the minor axis direction, of liquid crystals included in the plurality of lenses 231 as described above. The refractive index of the filler layer 240 may be smaller than a refractive index, in the major axis direction, of the liquid crystal included in the lens 231. Accordingly, light passing through the plurality of lenses 231 may or may not be refracted at the interface.

Referring to FIGS. 4 and 5, in the first type of light field display, the display panel may include a substrate SUB, a thin-film transistor layer TFTL, a light-emitting element layer EML, and an encapsulation film TFE. Components having substantially the same functions as those of the second type of light field display described above will be denoted by the same reference numerals, and any repetitive description thereof will be omitted.

A polarizing member 257 may be disposed between the display panel and a first base substrate 210. The light emitted from the display panel may vibrate in all directions. The polarizing member 257 may pass only light vibrating in a specific direction among the light emitted from the display panel and block the other light. In an embodiment, the polarizing member 257 may pass only light having the path PDX in the first linear polarization direction among the light emitted from the display panel, but embodiments of the present disclosure are not limited thereto.

A third driving electrode 232 may be disposed between the first base substrate 210 and a second base substrate 220, and a fourth driving electrode 233 may be disposed between the first base substrate 210 and the third driving electrode 232. An optical lens unit including lenses 231, a black matrix 235, and a light reflecting portion 236 may be disposed between the third driving electrode 232 and the fourth driving electrode 233. A filler layer 240 may be disposed on the optical lens unit, but as described above, an upper and lower relationship between the optical lens unit and the filler layer 240 is not limited to that illustrated in FIGS. 4 and 5.

Voltages may be applied to the third driving electrode and the fourth driving electrode, and the lens 231 may include liquid crystals that are birefringent materials. An arrangement of the liquid crystals in the lens 231 may be changed depending on the difference between the voltages applied to the third driving electrode 232 and the fourth driving electrode 233.

Referring to FIG. 4, a difference between the voltage applied to the third driving electrode 232 and the voltage applied to the fourth driving electrode 233 during a two-dimensional image display period may be a selected value or more. Light passing through the display panel may have a path PDX in the first linear polarization direction. The first linear polarization direction may coincide with or be parallel to a minor axis direction of the liquid crystal in the lens 231. Since the light passes through the light crystal while experiencing a refractive index of the liquid crystal in the minor axis direction and the refractive index of the liquid crystal in the minor axis direction is the same as a refractive index of the filler layer 240, the light may not be refracted at an interface. The two-dimensional image may be implemented from the first type of light field display by the light that is not refracted.

Referring to FIG. 5, a difference between the voltage applied to the third driving electrode 232 and the voltage applied to the fourth driving electrode 233 during a three-dimensional image display period may be a selected value or less. Light passing through the display panel may have the path PDX in the first linear polarization direction. The first linear polarization direction may coincide with or be parallel to a major axis direction of the liquid crystal in the lens 231. Since the light passes through the light crystal while experiencing a refractive index of the liquid crystal in the major axis direction and the refractive index of the liquid crystal in the major axis direction is greater than the refractive index of the filler layer 240, the light may be refracted at the interface. The three-dimensional image may be implemented from the first type of light field display by the refracted light. The refracted light may move toward a first view area V1, a second view area V2, and a third view area V3 according to mapped viewing angles.

It has been assumed in the above description that the refractive index of the filler layer 240 is the same as the refractive index of the lens 231 or the liquid crystal in the lens 231 in the minor axis direction and smaller than the refractive index of the lens 231 or the liquid crystal in the lens 231 in the major axis direction. In addition, it has been assumed that the linear polarization direction is specified in the first type and the second type light field displays. In addition, it has been assumed that the two-dimensional image is implemented in the first type of light field display when the voltages are applied to the third driving electrode 232 and the fourth driving electrode 233 and the three-dimensional image is implemented in the first type of light field display when the voltages are not applied to the third driving electrode 232 and the fourth driving electrode 233. In addition, it has been assumed that the two-dimensional image is implemented in the second type of light field display when the voltages are not applied to the first driving electrode 251 and the second driving electrode 252 and the three-dimensional image is implemented in the second type of light field display when the voltages are applied to the first driving electrode 251 and the second driving electrode 252.

Accordingly, the described configurations can be flexibly adapted to employ refractive index modulation, polarization control, or combined voltage-driving schemes to balance 2D image sharpness and 3D depth reproduction. This adaptability allows the display device according to embodiments to improve performance for varying content types, viewing conditions, or user preferences, thereby broadening the range of applications for hybrid 2D/3D display technology.

However, this is only an example for convenience of explanation, and embodiments are not limited thereto. For example, according to embodiments, uniformity, and the like, and variables such as, e.g., a refractive index range based on birefringence characteristics of the liquid crystal, a refractive index value of the filling layer, and a linear polarization direction of light passing through individual components may be adjusted.

However, in the first type of light field display, the major axis direction and the minor axis direction of the liquid crystal in the lens 231 may be directly changed, and in the second type of light field display, the linear polarization direction of the light passing through the display panel may be directly changed.

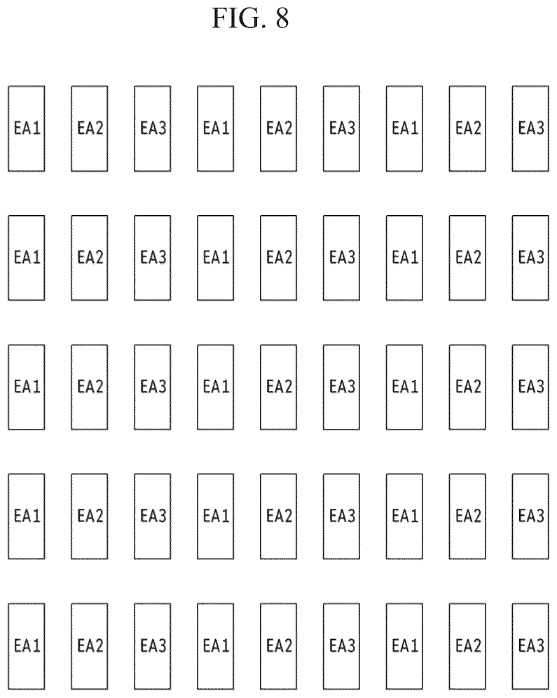

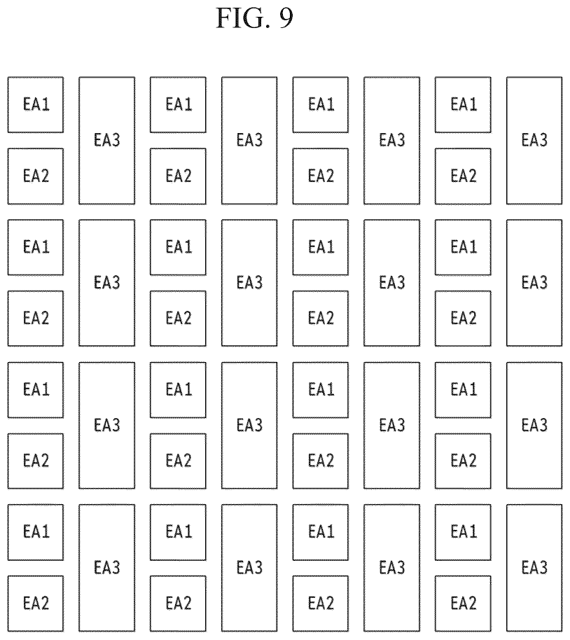

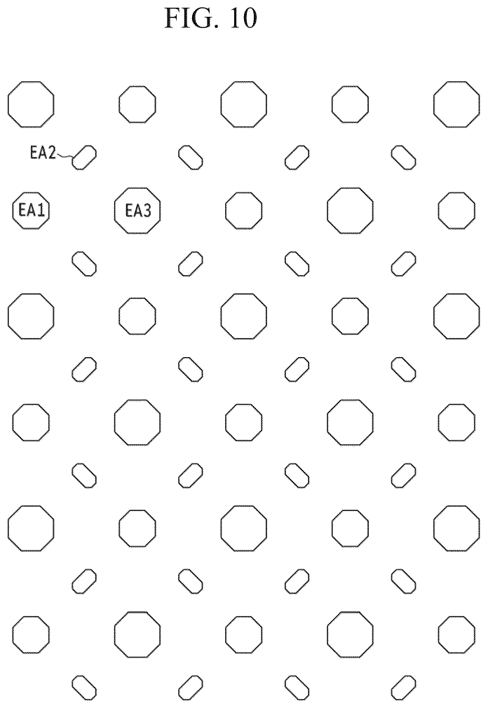

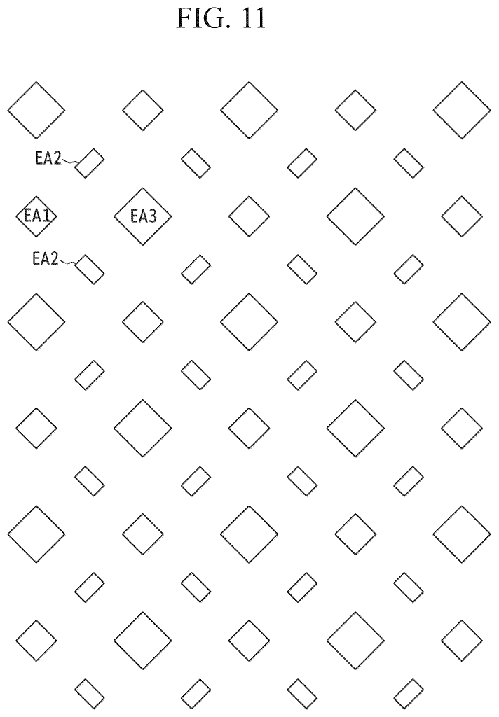

FIG. 8 is a plan view illustrating an arrangement structure of pixels according to various embodiments of the present disclosure. FIG. 9 is a plan view illustrating an arrangement structure of pixels according to various embodiments of the present disclosure. FIG. 10 is a plan view illustrating an arrangement structure of pixels according to various embodiments of the present disclosure. FIG. 11 is a plan view illustrating an arrangement structure of pixels according to various embodiments of the present disclosure.

In the display device according to embodiments of the present disclosure, the pixel disposed in the display panel may include a plurality of sub-pixels. For example, one pixel may include a first sub-pixel, a second sub-pixel, and a third sub-pixel. The first sub-pixel may implement a first color, the second sub-pixel may implement a second color, and the third sub-pixel may implement a third color. Each of the first color, the second color, and the third color may be any one of, for example, a red color, a green color, and a blue color so that these colors do not overlap each other. For example, the first color may be a red color, the second color may be a green color, and the third color may be a blue color, but embodiments of the present disclosure are not limited thereto.

In the display device according to embodiments of the present disclosure, the respective sub-pixels may include a plurality of emission areas in a plan view. For example, the first sub-pixel may include a first emission area EA1, the second sub-pixel may include a second emission area EA2, and the third sub-pixel may include a third emission area EA3. A black matrix or the like may be disposed between the plurality of emission areas EA1, EA2, and EA3. The black matrix may improve external light visibility of the display device by absorbing light incident from the outside of the display device.

FIGS. 8 to 11 illustrate various arrangement structures of the first emission area EA1 to the third emission area EA3. In a plan view, the plurality of emission areas may be disposed in a stripe shape as illustrated in FIG. 8. In a plan view, the plurality of emission areas may also be arranged in a Pentile shape as illustrated in FIG. 9 to FIG. 11. Through the arrangement of the emission areas in the Pentile shape, the number of sub-pixels disposed in the display panel may be reduced, and a lifespan of a sub-pixel of a color with relatively low light emitting efficiency may be complemented.

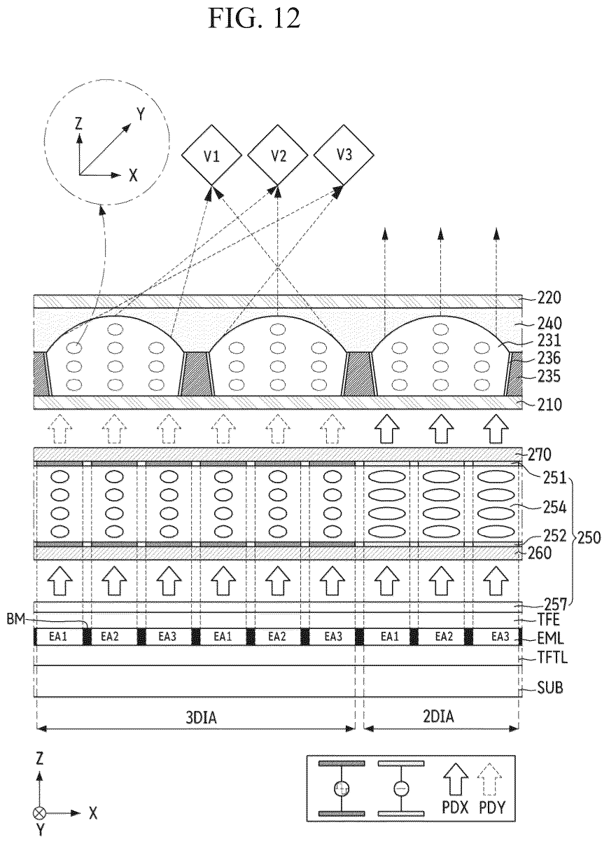

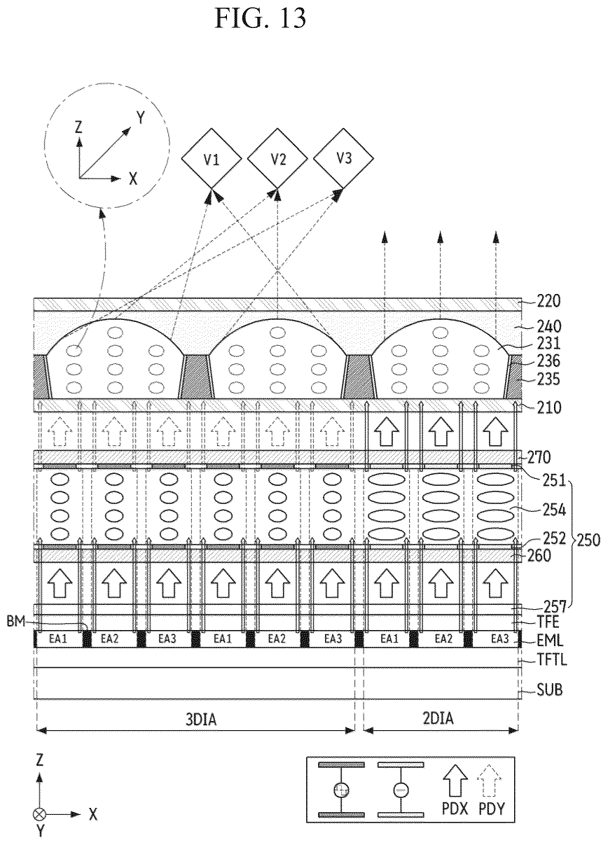

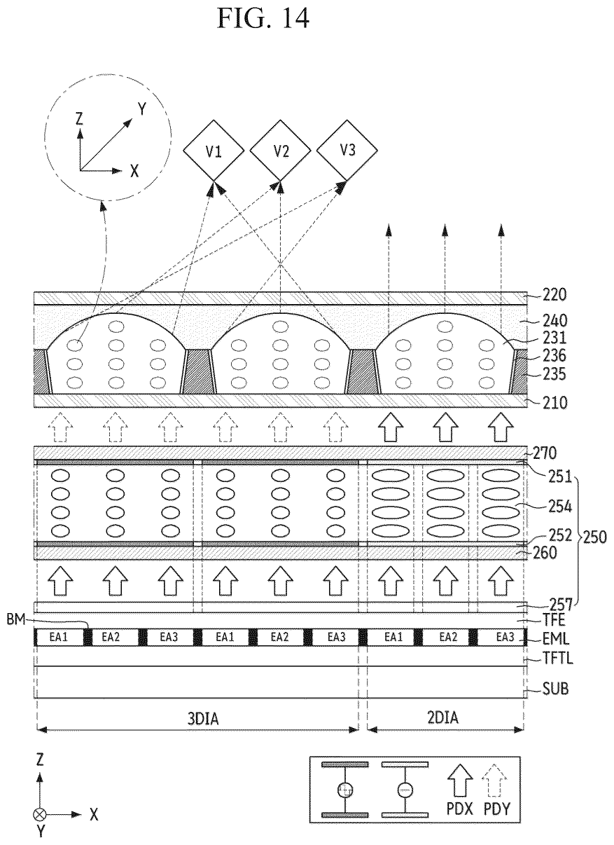

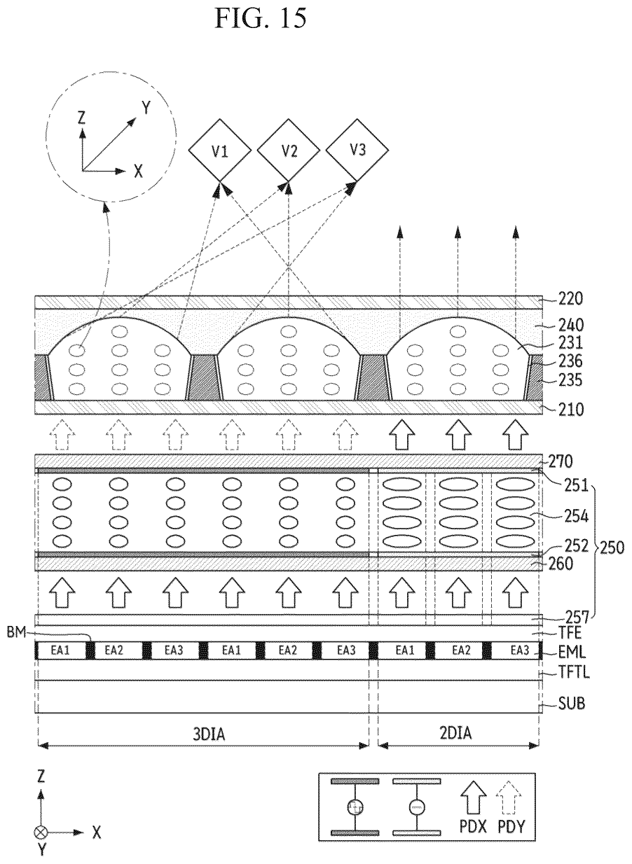

FIG. 12 is a cross-sectional view illustrating a display device according to an embodiment of the present disclosure. FIG. 13 is a cross-sectional view illustrating a display device according to an embodiment of the present disclosure. FIG. 14 is a cross-sectional view illustrating a display device according to an embodiment of the present disclosure. FIG. 15 is a cross-sectional view illustrating a modified example of FIG. 14.

Referring to FIG. 12, a display device according to an embodiment of the present disclosure may include a first area 2DIA and a second area 3DIA. A two-dimensional image may be implemented in the first area, and a three-dimensional image may be implemented in the second area. The display device may simultaneously implement the two-dimensional image and the three-dimensional image by including a plurality of driving electrodes overlapping each of the first area and the second area.

In embodiments, optical separation between the first area 2DIA and the second area 3DIA may be enhanced by configuring the driving electrodes in each area to induce distinct polarization states that reduce crosstalk between adjacent two-dimensional and three-dimensional image regions. This separation may be further reinforced by improving the alignment layer orientation of the driving liquid crystals 254 in each area so that light leakage between areas is reduced, thereby maintaining high image fidelity for both modes when displayed simultaneously.

The display panel may include first emission areas EA1, second emission areas EA2, and third emission areas EA3. A black matrix BM may be disposed between the respective emission areas. The black matrix BM may reduce external light reflectivity by absorbing external light incident from the outside of the display device. The black matrix BM may include a black material capable of absorbing light of various wavelength ranges.

A plurality of emission areas may include a first pixel emission area and a second pixel emission area. A plurality of emission areas included in the first pixel emission area may be disposed in the first area. A plurality of emission areas included in the second pixel emission area may be disposed in the second area. Each of the first pixel emission area and the second pixel emission area may include a first emission area EA1, a second emission area EA2, and a third emission area EA3. The first emission area EA1 may implement a first color, the second emission area EA2 may implement a second color, the third emission area EA3 may implement a third color, and each of the first color, the second color, and the third color may be any one of, for example, a red color, a green color, and a blue color so that these colors do not overlap each other.

In the second type of light field display illustrated in FIG. 12, the first driving electrode 251 and the second driving electrode 252 may be disposed between the third base substrate 260 and the fourth base substrate 270 disposed on the polarizing member 257. The first driving electrode 251 may be disposed between the third base substrate 260 and the fourth base substrate 270, and the second driving electrode 252 may be disposed between the third base substrate 260 and the first driving electrode 251. The driving liquid crystals 254 may be disposed between the first driving electrode 251 and the second driving electrode 252.

As described above, in the second type of light field display, the linear polarization direction of the light passing through the display panel may be directly changed. For example, an implemented image may be determined according to whether the linear polarization direction of the light is changed. It has been assumed by way of example in the present disclosure that the three-dimensional image is implemented in an area where the linear polarization direction of the light is changed and the two-dimensional image is implemented in an area where the linear polarization direction of the light is not changed, but embodiments of the present disclosure are not limited thereto. For example, the display device may be modified so that the two-dimensional image is implemented in the area where the linear polarization direction of the light is changed.

When the linear polarization direction is altered for the implementation of the three-dimensional image, the polarization rotation may be precisely controlled to match the requirements of the optical lens unit or parallax element positioned above the display panel. This control may allow for the perceived depth and parallax cues of the three-dimensional image to remain accurate while the two-dimensional image retains full resolution and brightness in its designated region. In some implementations, the polarization rotation angle may be adjustable in real time through modulation of the voltage applied to the first driving electrodes 251 and second driving electrodes 252, allowing adaptive switching between modes or fine-tuning for varying viewing environments.

Each of the number of first driving electrode 251 and the number of second driving electrode 252 may be plural. For example, the first driving electrode 251 may include a plurality of first driving electrodes 251 respectively overlapping the plurality of emission areas disposed in the display panel. The second driving electrode 252 may include a plurality of second driving electrodes 252 respectively overlapping the plurality of emission areas disposed in the display panel.

For example, the first driving electrode 251 may include first driving electrodes 251 overlapping the plurality of emission areas disposed in the first pixel emission area and first driving electrodes 251 overlapping the plurality of emission areas disposed in the second pixel emission area. The first driving electrodes 251 overlapping the plurality of emission areas disposed in the first pixel emission area may be disposed in the first area, and the first driving electrodes 251 overlapping the plurality of emission areas disposed in the second pixel emission area may be disposed in the second area. The first driving electrode 251 may include the first driving electrode 251 disposed in the first area and the first driving electrode 251 disposed in the second area.

The second driving electrode 252 may include second driving electrodes 252 overlapping the plurality of emission areas disposed in the first pixel emission area and second driving electrodes 252 overlapping the plurality of emission areas disposed in the second pixel emission area. The second driving electrodes 252 overlapping the plurality of emission areas disposed in the first pixel emission area may be disposed in the first area, and the second driving electrodes 252 overlapping the plurality of emission areas disposed in the second pixel emission area may be disposed in the second area. The second driving electrode 252 may include the second driving electrode 252 disposed in the first area and the second driving electrode 252 disposed in the second area.

In an embodiment, the first driving electrode 251 disposed in the first area may include a plurality of first driving electrodes 251 respectively overlapping the plurality of emission areas disposed in the first pixel emission area. The first driving electrode 251 disposed in the second area may include a plurality of first driving electrodes 251 respectively overlapping the plurality of emission areas disposed in the second pixel emission area. In an embodiment, a plurality of first driving electrodes 251 may be implemented to overlap a plurality of sub-pixels corresponding to the plurality of emission areas. In other words, the plurality of first driving electrodes 251 may be formed to respectively overlap the plurality of sub-pixels.

In an embodiment, the second driving electrode 252 disposed in the first area may include a plurality of second driving electrodes 252 respectively overlapping the plurality of emission areas disposed in the first pixel emission area. The second driving electrode 252 disposed in the second area may include a plurality of second driving electrodes 252 respectively overlapping the plurality of emission areas disposed in the second pixel emission area. In an embodiment, a plurality of second driving electrodes 252 may be implemented to overlap a plurality of sub-pixels corresponding to the plurality of emission areas. In other words, the plurality of second driving electrodes 252 may be formed to respectively overlap the plurality of sub-pixels.

A first voltage may be applied to the plurality of first driving electrodes 251 disposed in the first area. A second voltage may be applied to the plurality of first driving electrodes 251 disposed in the second area. A third voltage may be applied to the plurality of second driving electrodes 252 disposed in the first area. A fourth voltage may be applied to the plurality of second driving electrodes 252 disposed in the second area.

In an embodiment, the first voltage and the third voltage may be applied to the driving electrodes disposed in the first area, and the second voltage and the fourth voltage may be applied to the driving electrodes disposed in the second area.

The driving liquid crystals 254 disposed in the first area may be arranged according to a difference between the first voltage and the third voltage, and the driving liquid crystals 254 disposed in the second area may be arranged according to a difference between the second voltage and the fourth voltage.

This voltage differential-based control of the driving liquid crystals 254 according to embodiments allows each area to maintain a unique polarization state, which may aid in preventing unintended optical interference between the two-dimensional and three-dimensional regions. By maintaining distinct polarization orientations, the optical elements responsible for generating the three-dimensional effect (e.g., lenticular lenses or parallax barriers) may only interact with the intended image data, while the two-dimensional region may remain unaffected by such optical processing. As a result, image sharpness and depth perception may both be improved without sacrificing panel efficiency according to embodiments of the present disclosure.

In an embodiment, the first area may implement the two-dimensional image, and the second area may implement the three-dimensional image. For example, the voltages applied to the first driving electrode 251 and the second driving electrode 252 in order to implement the two-dimensional image may be different from the voltages applied to the first driving electrode 251 and the second driving electrode 252 in order to implement the three-dimensional image.

In an embodiment, the voltages applied to the first driving electrode 251 and the second driving electrode 252 in order to implement the two-dimensional image may be lower than the voltages applied to the first driving electrode 251 and the second driving electrode 252 in order to implement the three-dimensional image. However, embodiments of the present disclosure are not limited thereto.

For example, the first voltage may be lower than the second voltage, and the third voltage may be lower than the fourth voltage. An absolute value of the difference between the first voltage and the third voltage may be smaller than an absolute value of the difference between the second voltage and the fourth voltage. Accordingly, the two-dimensional image may be implemented in the first area, and the three-dimensional image may be implemented in the second area.

The display device according to an embodiment of the present disclosure may include a plurality of driving electrodes formed in a size of an emission area level corresponding to the sub-pixel. Accordingly, it may be determined whether the two-dimensional image or the three-dimensional image will be implemented from the light emitted from the respective emission areas.

In an embodiment, by forming the driving electrodes at the sub-pixel level, the control circuitry can independently address each emission area, allowing per-sub-pixel polarization modulation. This fine-grained control may provide an additional degree of freedom in improving brightness, contrast, and color balance independently for the two-dimensional and three-dimensional regions. In embodiments, this may enable local adjustments to polarization without requiring changes to the entire area, which can be utilized in applications involving dynamic reallocation of 2D and 3D zones on the same display.

For example, an arrangement of the driving liquid crystals 254 disposed in the first area may be determined by the difference between the first voltage applied to the first driving electrode 251 disposed in the first area and the third voltage applied to the second driving electrode 252 disposed in the first area. In addition, an arrangement of the driving liquid crystals 254 disposed in the second area may be determined by the difference between the second voltage applied to the first driving electrode 251 disposed in the second area and the fourth voltage applied to the second driving electrode 252 disposed in the second area. The arrangements of the driving liquid crystals 254 disposed in the first area and the driving liquid crystals 254 disposed in the second area may be different from each other. Accordingly, a linear polarization direction of light passing through the driving liquid crystal 254 in the first area may be different from a linear polarization direction of light passing through the driving liquid crystal 254 in the second area. Accordingly, the first area and the second area may implement images of different dimensions, respectively.

Referring to FIG. 13, the plurality of first driving electrodes 251 and second driving electrodes 252 disposed in the first area may be formed in a size smaller than that of the emission areas. In addition, the plurality of first driving electrodes 251 and second driving electrodes 252 disposed in the second area may also be formed in a size smaller than that of the emission areas. Each of the plurality of first driving electrodes 251 and second driving electrodes 252 may be formed in a size of an emission area level, but may be formed to be smaller than a size of an individual emission area.

The first driving electrode 251 and the second driving electrode 252 may be made of a transparent conductive material (TCO) such as ITO or IZO capable of transmitting light or a semi-transmissive conductive material such as, for example, magnesium (Mg), silver (Ag), or an alloy of magnesium (Mg) and silver (Ag).

In an embodiment, the first driving electrode 251 and the second driving electrode 252 are made of a transparent material, but transmittance of light passing through the first driving electrode 251 and the second driving electrode 252 may not be 100% and may be less than 100%. According to an embodiment, a size of an individual driving electrode is smaller than a size of an individual emission area, and thus, amounts of light passing through the first driving electrode 251 and the second driving electrode 252 may relatively increase. Accordingly, luminance or the like of the display device may be relatively improved, such that the display quality of the display device may be improved.

Referring to FIG. 14, the first driving electrode 251 formed in the first area and the second driving electrode 252 formed in the first area may be formed in a size of a pixel level. The first driving electrode 251 formed in the second area and the second driving electrode 252 formed in the second area may be formed in a size of a pixel level.

For example, the pixel may include a plurality of emission areas. The pixel may include first to third emission areas EA1, EA2, and EA3. Each of the first driving electrode 251 and the second driving electrode 252 may be formed as an integrated electrode so as to correspond to the size of the pixel level including the first driving electrode 251 and the second driving electrode 252. The first driving electrode 251 formed in the size of the pixel level may have a greater size than the first driving electrode 251 formed in a size of a sub-pixel level. The second driving electrode 252 formed in the size of the pixel level may have a greater size than the second driving electrode 252 formed in a size of a sub-pixel level.

Referring to FIG. 15, the first driving electrode 251 formed in the second area and the second driving electrode 252 formed in the second area may be formed in a size of a unit pixel level. A unit pixel may include a plurality of pixels, and one pixel may include a plurality of sub-pixels. Each of the first driving electrode 251 and the second driving electrode 252 may be formed as an integrated electrode so as to correspond to the size of the unit pixel level including the plurality of pixels.

The first driving electrode 251 formed in the size of the unit pixel level may have a greater size than the first driving electrode 251 formed in the size of the pixel level. The second driving electrode 252 formed in the size of the unit pixel level may have a greater size than the second driving electrode 252 formed in the size of the pixel level.

The driving electrodes according to embodiments of the present disclosure may be formed in the size of the sub-pixel level, which is the smallest unit, or formed in the size of the unit pixel level, which is a relatively great size, as described above. According to embodiments, By adjusting the number and sizes of driving electrodes corresponding to the first area and the second area, production efficiency may be improved and manufacturing cost may be reduced.

According to embodiments, adjusting the number and sizes of the driving electrodes not only influences manufacturing cost but also affects the achievable resolution and image uniformity in each mode. For example, smaller electrodes at the sub-pixel level may be utilized for applications involving high-precision polarization control and reduced crosstalk between sub-pixels, whereas larger electrodes at the unit pixel level may be utilized for applications involving simplifying wiring layouts and reducing driving complexity. Accordingly, the electrode sizing strategy may be selected based on a trade-off between optical performance and manufacturing efficiency, and different strategies may be applied to the first area and the second area within the same display panel.

The second type of light field display has been mainly described in the above-described embodiments, but various modifications may be made departing from the technical spirit disclosed in the present disclosure. For example, also in the first type of light field display, it is possible to simultaneously implement a two-dimensional image and a three-dimensional image by forming the third driving electrodes and the fourth driving electrodes for each area.

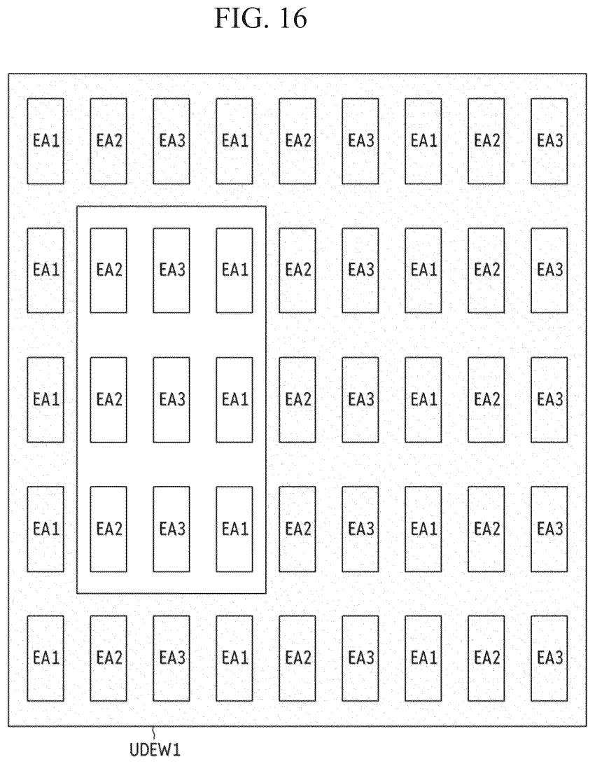

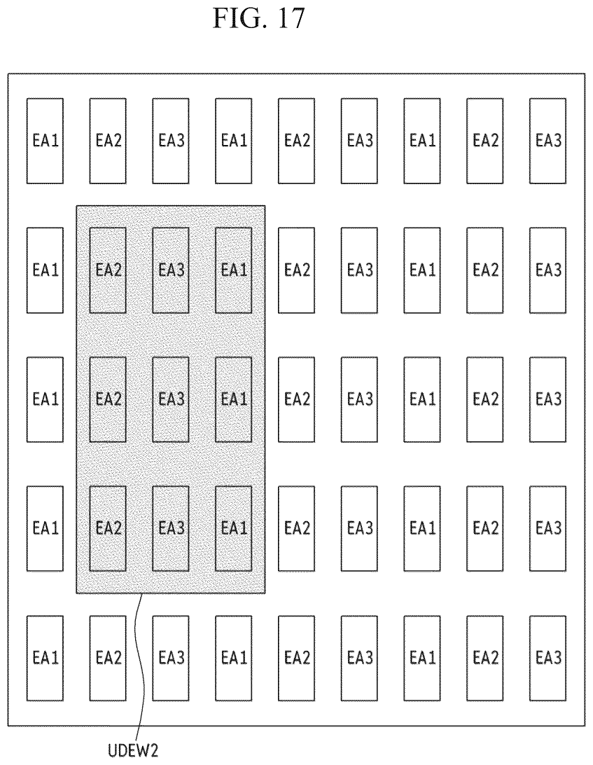

FIG. 16 is a plan view illustrating a driving electrode disposed in a first area of a display device according to an embodiment of the present disclosure. FIG. 17 is a plan view illustrating a driving electrode disposed in a second area of the display device according to an embodiment of the present disclosure. An arrangement structure of pixels having a stripe shape has been illustrated in FIGS. 16 and 17, but embodiments of the present disclosure are not limited thereto.

Referring to FIGS. 16 and 17, the display device may include a unit driving electrode disposed in the first area and a unit driving electrode disposed in the second area. In an embodiment, each of the unit driving electrode disposed in the first area and the unit driving electrode disposed in the second area may be formed as an integrated electrode. For example, each unit driving electrode may be formed as one connected electrode. However, embodiments of the present disclosure are not limited thereto.

The unit driving electrode disposed in the first area may include a first driving electrode 251 disposed in the first area and a second driving electrode 252 disposed in the first area. The unit driving electrode disposed in the second area may include a first driving electrode 251 disposed in the second area and a second driving electrode 252 disposed in the second area. The first driving electrode 251 and the second driving electrode 252 disposed in a vertical direction may be referred to as one integrated electrode in a plan view.

The unit driving electrode disposed in the first area may apply a voltage to the driving liquid crystals 254 disposed in the first area to switch an arrangement of the driving liquid crystals, and the unit driving electrode disposed in the second area may apply a voltage to the driving liquid crystal 254 disposed in the second area to switch an arrangement of the driving liquid crystals. In an embodiment, the unit driving electrode disposed in the first area and the unit driving electrode disposed in the second area may be formed to be physically separated from each other. Accordingly, the first area and the second area may implement a two-dimensional image and a three-dimensional image, respectively.

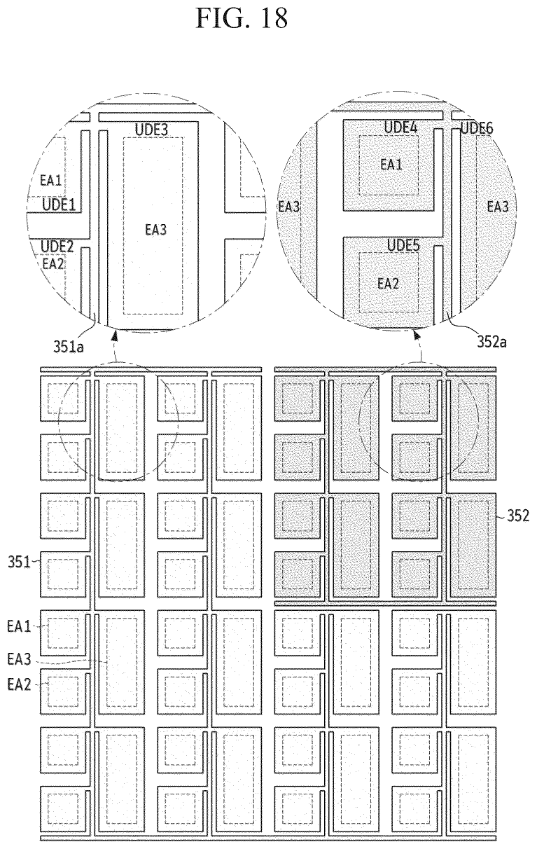

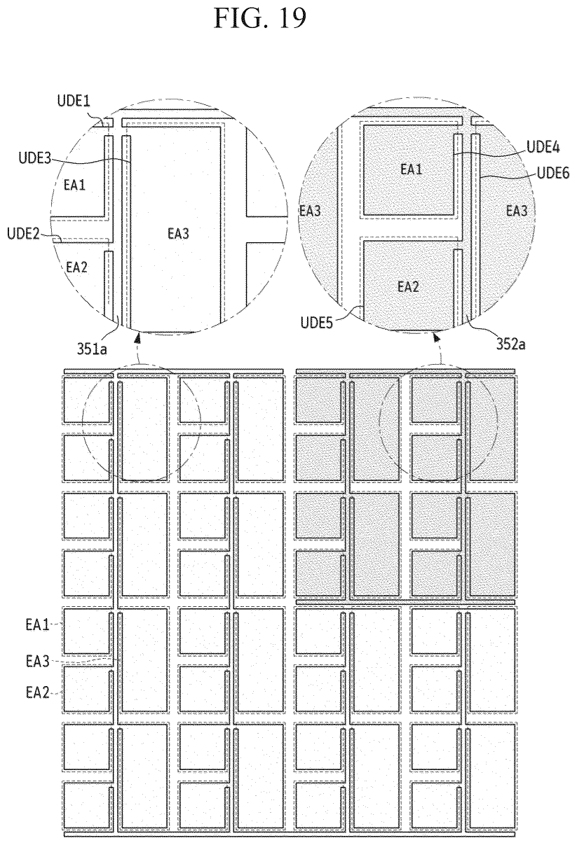

FIG. 18 is a plan view illustrating a display device according to an embodiment of the present disclosure. FIG. 19 is a plan view illustrating the display device according to an embodiment of the present disclosure. An arrangement structure of pixels having a Pentile shape has been illustrated in FIGS. 18 and 19, but embodiments of the present disclosure are not limited thereto.

The display device according to embodiments of the present disclosure may be implemented in a passive matrix (PM) manner in which it operates so that the same voltage is applied to all unit driving electrodes disposed in the same area. Accordingly, a first integrated electrode 351 may adjust images implemented from the first area at a time, and a second integrated electrode 352 may adjust images implemented from the second area at a time.

Referring to FIG. 18, a unit driving electrode UDEW1 disposed in the first area may include the first integrated electrode 351 formed to correspond to each of the plurality of emission areas disposed in the first area. A unit driving electrode UDEW2 disposed in the second area may include the second integrated electrode 352 formed to correspond to each of the plurality of emission areas disposed in the second area. Each of the first integrated electrode 351 and the second integrated electrode 352 may include a first driving electrode 251 and a second driving electrode 252 disposed in the vertical direction.

Referring to an enlarged view of FIG. 18, the first integrated electrode 351 may include a first unit driving electrode UDE1 formed to correspond to the first emission area EA1, a second unit driving electrode UDE2 formed to correspond to the second emission area EA2, and a third unit driving electrode UDE3 formed to correspond to the third emission area EA3.

The second integrated electrode 352 may include a fourth unit driving electrode UDE4 formed to correspond to the first emission area EA1, a fifth unit driving electrode UDE5 formed to correspond to the second emission area EA2, and a sixth unit driving electrode UDE6 formed to correspond to the third emission area EA3.

In an embodiment, the first to sixth unit driving electrodes UDE1, UDE2, UDE3, UDE4, UDE5, and UDE6 may have sizes greater than sizes of the corresponding emission areas, respectively. Since the first to third unit driving electrodes UDE1, UDE2, and UDE3 are included in the first integrated electrode 351 disposed in the first area, a two-dimensional image may be implemented from the first to third unit driving electrodes UDE1, UDE2, and UDE3. Since the fourth to sixth unit driving electrodes UDE4, UDE5, and UDE6 are included in the second integrated electrode 352 disposed in the second area, a three-dimensional image may be implemented from the fourth to sixth unit driving electrodes UDE4, UDE5, and UDE6. However, embodiments of the present disclosure are not limited thereto.

For example, a first voltage and a third voltage may be applied to the first to third unit driving electrodes UDE1, UDE2, and UDE3 included in the first integrated electrode 351, and a second voltage and a fourth voltage may be applied to the fourth to sixth unit driving electrodes UDE4, UDE5, and UDE6 included in the second integrated electrode 352.

In order to improve efficiency in terms of electrode manufacturing cost, the first integrated electrode 351 may include a first line electrode 351a connecting the first to third unit driving electrodes UDE1, UDE2, and UDE3 to each other, and the second integrated electrode 352 may include a second line electrode 352a connecting the fourth to sixth unit driving electrodes UDE4, UDE5, and UDE6 to each other. The first line electrode 351a connects the unit driving electrodes UDEW1 disposed in the first area to each other, such that the same voltage may be applied to all the driving liquid crystals 254 disposed in the first area. The second line electrode 352a connects the unit driving electrodes UDEW2 disposed in the second area to each other, such that the same voltage may be applied to all the driving liquid crystals 254 disposed in the second area.

Unnecessary electrodes may not be disposed in the remaining areas except for the line electrodes for applying the same voltage to the unit driving electrodes disposed in the same areas and the unit driving electrodes connected to the line electrodes, and accordingly, manufacturing cost of the display device may be reduced.

Referring to FIG. 19, a size of the plurality of unit driving electrodes may be smaller than a size of an emission area corresponding to each unit driving electrode. As described above, even though the driving electrode is made of a transparent material, transmittance of the light passing through the driving electrode may be less than 100%. Accordingly, by making the size of the driving electrode relatively smaller than the size of the emission area, the transmittance of the light may be increased, and display luminance of the display device may be improved.

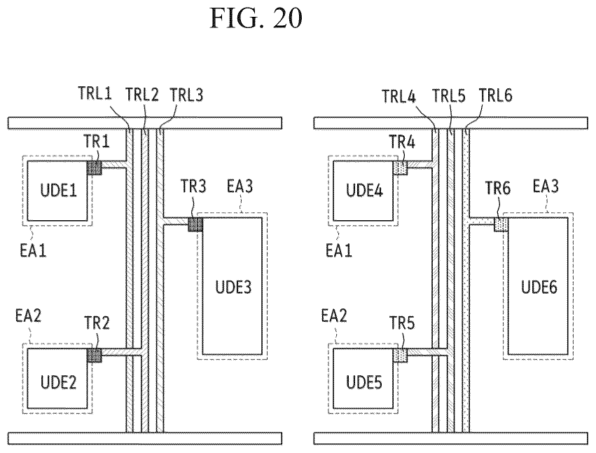

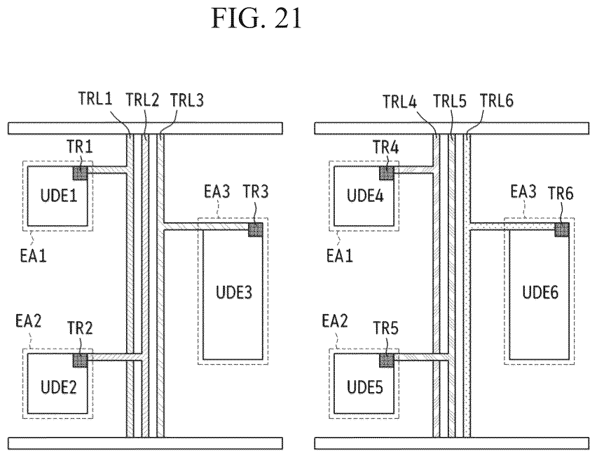

FIGS. 20 and 21 are plan views illustrating transistors disposed in a display device according to an embodiment of the present disclosure.

The display device according to embodiments of the present disclosure may be implemented in an active matrix (AM) manner in which it operates so that all of voltages respectively applied to the unit driving electrodes may be individually adjusted. Here, a plurality of transistors for individually adjusting the respective unit driving electrodes may be additionally disposed, and a plurality of lines for adjusting the turn-on or turn-off of the transistors may be additionally disposed.

Referring to FIG. 20, the first area may include a first transistor TR1 electrically connected to the first unit driving electrode UDE1, a second transistor TR2 electrically connected to the second unit driving electrode UDE2, and a third transistor TR3 electrically connected to the third unit driving electrode UDE3. The second area may include a fourth transistor TR4 electrically connected to the fourth unit driving electrode UDE4, a fifth transistor TR5 electrically connected to the fifth unit driving electrode UDE5, and a sixth transistor TR6 electrically connected to the sixth unit driving electrode UDE6.

Unlike the PM manner described above, in an embodiment according to FIG. 20, voltages applied to the unit driving electrodes corresponding to the respective emission areas may be individually adjusted. For example, different voltages may be applied to the unit driving electrodes disposed in the same area. In the display device implemented in the PM manner described above, the first integrated electrode 351 and the second integrated electrode 352 are fixedly formed from a time when the display device is manufactured, and the first area and the second area cannot be physically fixed. However, in the display device implemented in the AM manner, the first area and the second area may not be defined as physically fixed locations. For example, voltages applied to the first unit driving electrode UDE1, the fourth unit driving electrode UDE4, and the sixth unit driving electrode UDE6 may be the same as each other, and voltages applied to the second unit driving electrode UDE2, the third unit driving electrode UDE3, and the fifth unit driving electrode UDE5 may be the same as each other. An area where a two-dimensional image is implemented and an area where a three-dimensional image is implemented may be set by changing voltages applied to individual unit driving electrodes.

To this end, the first line electrode 351a may include a first transistor line TRL1 electrically connected to the first transistor TR1, a second transistor line TRL2 electrically connected to the second transistor TR2, and a third transistor line TRL3 electrically connected to the third transistor TR3. The second line electrode 352a may include a fourth transistor line TRL4 electrically connected to the fourth transistor TR4, a fifth transistor line TRL5 electrically connected to the fifth transistor TR5, and a sixth transistor line TRL6 electrically connected to the sixth transistor TR6. Each transistor line may include a plurality of lines for applying voltages to each of a gate electrode and source/drain electrodes of the transistor.

For example, as the transistor is disposed, transmittance of light in an area where the transistor is disposed may be relatively lower than that of the unit driving electrode. Accordingly, a problem that luminance of the display device entirely decreases may occur by disposing the transistor. Accordingly, the first to sixth transistors TR1, TR2, TR3, TR4, TR5, and TR6 may not overlap the first to sixth unit driving electrodes UDE1, UDE2, UDE3, UDE4, UDE5, and UDE6, respectively, in the thickness direction of the display device. The plurality of transistors applying the voltages to the respective unit driving electrodes may not affect total amounts of light passing through the unit driving electrodes, and the luminance of the display device may be entirely maintained.

Referring to FIG. 21, the first to sixth transistors TR1, TR2, TR3, TR4, TR5, and TR6 may also overlap the first to sixth unit driving electrodes UDE1, UDE2, UDE3, UDE4, UDE5, and UDE6, respectively, in the thickness direction of the display device. Accordingly, a decrease in design area that may occur by disposing the first to sixth transistors TR6 may be prevented.

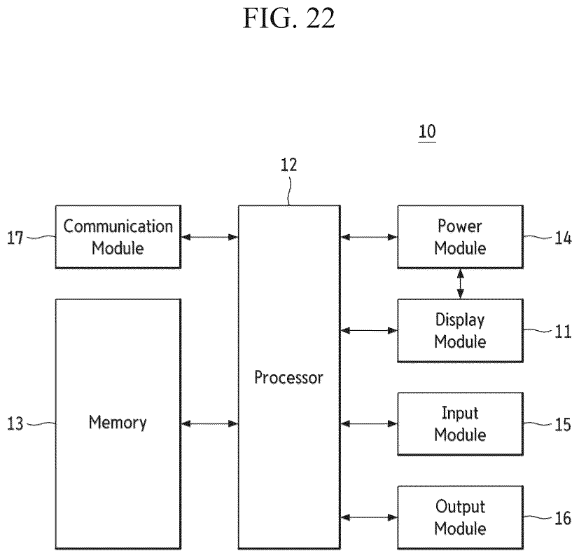

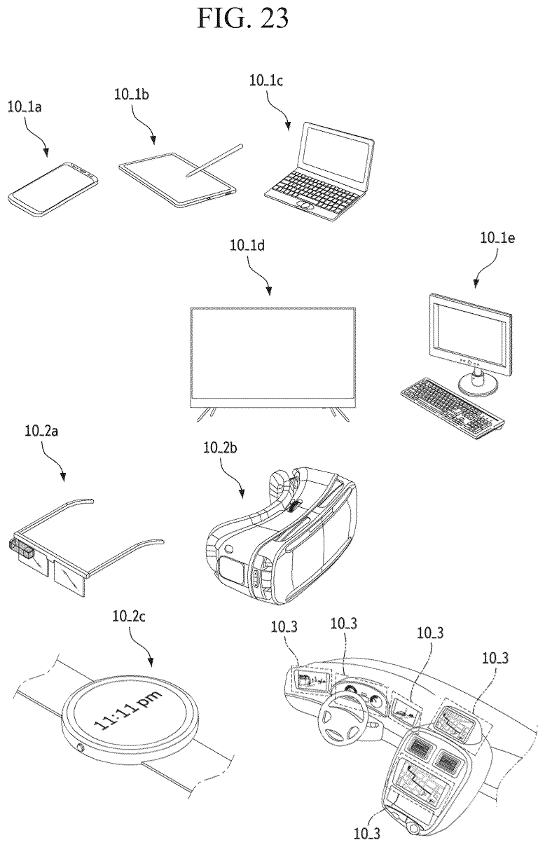

FIG. 22 is a block diagram of an electronic device according to an embodiment of the present disclosure. FIG. 23 is schematic views of electronic devices according to various embodiments of the present disclosure.

Referring to FIG. 22, an electronic device 10 according to an embodiment may include a display module 11, a processor 12, a memory 13, and a power module 14. The display module 11 may be the same as the display module 100 described above with reference to FIG. 1.

The processor 12 may include at least one of, for example, a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may convert power supplied by the power supply module to generate power necessary for an operation of the electronic device 10. The power module 14 may also be referred to as a power device.

At least one of the respective components of the above-described electronic device 10 may be included in the display device according to the above-described embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device rather than the display device.

Referring to FIG. 23, various electronic devices to which the display devices according to embodiments of the present disclosure are applied may include, for example, image display electronic devices such as a smartphone 10_1a, a tablet computer 10_1b, a laptop computer 10_1c, a television (TV) 10_1d, and a computer monitor 10_1e. Furthermore, the various electronic devices to which the display devices according to embodiments of the present disclosure are applied may include wearable electronic devices including display modules, such as a smart glasses 10_2a, a head mounted display 10_2b, and a smart watch 10_2c, and vehicle electronic devices 10_3 including display modules, such as a center information display (CID) disposed on an instrument board, a center fascia, or a dashboard of a vehicle and a room mirror display.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In embodiments, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a display panel including a plurality of emission areas and a black matrix disposed between the plurality of emission areas;
a plurality of second driving electrodes disposed on the display panel and overlapping the plurality of emission areas, respectively;
a plurality of first driving electrodes disposed on the plurality of second driving electrodes and overlapping the plurality of emission areas, respectively;
a driving liquid crystal disposed between the plurality of second driving electrodes and the plurality of first driving electrodes; and
an optical lens unit disposed on the plurality of first driving electrodes and including a plurality of lenses.

2. The display device of claim 1, wherein the plurality of emission areas include:
a first emission area configured to emit light having a first color;
a second emission area configured to emit light having a second color; and
a third emission area configured to emit light having a third color.

3. The display device of claim 2, wherein the first color, the second color, and the third color comprise red, green, and blue, respectively.

4. The display device of claim 1, wherein the plurality of emission areas include a first pixel emission area and a second pixel emission area, and
each of the first pixel emission area and the second pixel emission area includes:
a first emission area configured to emit light having a first color;
a second emission area configured to emit light having a second color; and
a third emission area configured to emit light having a third color.

5. The display device of claim 4, wherein the first color, the second color, and the third color comprise red, green, and blue, respectively.

6. The display device of claim 1, wherein the plurality of emission areas include an emission area disposed in a first area and an emission area disposed in a second area, and
the plurality of first driving electrodes include a first driving electrode disposed in the first area and a first driving electrode disposed in the second area.

7. The display device of claim 6, wherein a first voltage applied to the first driving electrode disposed in the first area is different from a second voltage applied to the first driving electrode disposed in the second area.

8. The display device of claim 7, wherein the first voltage is lower than the second voltage.

9. The display device of claim 1, wherein the plurality of emission areas include an emission area disposed in a first area and an emission area disposed in a second area, and
the plurality of second driving electrodes include a second driving electrode disposed in the first area and a second driving electrode disposed in the second area.

10. The display device of claim 9, wherein a third voltage applied to the second driving electrode disposed in the first area is different from a fourth voltage applied to the second driving electrode disposed in the second area.

11. The display device of claim 10, wherein the third voltage is lower than the fourth voltage.

12. The display device of claim 9, wherein the plurality of first driving electrodes include a first driving electrode disposed in the first area and a first driving electrode disposed in the second area.

13. The display device of claim 12, wherein a first voltage applied to the first driving electrode disposed in the first area is different from a second voltage applied to the first driving electrode disposed in the second area.

14. The display device of claim 12, wherein a difference between a first voltage applied to the first driving electrode disposed in the first area and a third voltage applied to the second driving electrode disposed in the first area is different from a difference between a second voltage applied to the first driving electrode disposed in the second area and a fourth voltage applied to the second driving electrode disposed in the second area.

15. The display device of claim 14, wherein the difference between the first voltage applied to the first driving electrode disposed in the first area and the third voltage applied to the second driving electrode disposed in the first area is smaller than the difference between the second voltage applied to the first driving electrode disposed in the second area and the fourth voltage applied to the second driving electrode disposed in the second area.

16. An electronic device, comprising:
a processor configured to provide an image signal;
a display device configured to receive the image signal provided from the processor and display an image; and
a power device configured to supply power to the display device,
wherein the display device includes:
a display panel including a plurality of emission areas and a black matrix disposed between the plurality of emission areas;
a plurality of second driving electrodes disposed on the display panel and overlapping the plurality of emission areas, respectively;
a plurality of first driving electrodes disposed on the plurality of second driving electrodes and overlapping the plurality of emission areas, respectively;
a driving liquid crystal disposed between the plurality of second driving electrodes and the plurality of first driving electrodes; and
an optical lens unit disposed on the plurality of first driving electrodes and including a plurality of lenses.

17. The electronic device of claim 16, wherein the plurality of emission areas include:
a first emission area configured to emit light having a first color;
a second emission area configured to emit light having a second color; and
a third emission area configured to emit light having a third color.

18. The electronic device of claim 16, wherein the plurality of emission areas include an emission area disposed in a first area and an emission area disposed in a second area, and
the plurality of first driving electrodes include a first driving electrode disposed in the first area and a first driving electrode disposed in the second area.

19. The electronic device of claim 18, wherein the plurality of second driving electrodes include a second driving electrode disposed in the first area and a second driving electrode disposed in the second area.

20. The electronic device of claim 19, wherein a difference between a first voltage applied to the first driving electrode disposed in the first area and a third voltage applied to the second driving electrode disposed in the first area is different from a difference between a second voltage applied to the first driving electrode disposed in the second area and a fourth voltage applied to the second driving electrode disposed in the second area.
